(19) United States
(12) Patent Application Publication
(10) Pub. No.: US 2026/0094627 A1
(43) Pub. Date: Apr. 2, 2026

(54) MEMORY DEVICE, FABRICATION METHOD THEREOF AND SYSTEM

(71) Applicant: Yangtze Memory Technologies Co., Ltd., Wuhan (CN)

(72) Inventors: Shiqi Huang, Wuhan (CN); Chunyuan Hou, Wuhan (CN); Liang Chen, Wuhan (CN); Yaqin Liu, Wuhan (CN); Wei Liu, Wuhan (CN)

(21) Appl. No.: 19/228,600

(22) Filed: Jun. 4, 2025

(30) Foreign Application Priority Data
Sep. 30, 2024 (CN) 202411392131.9

(51) Int. Cl. G11C 5/06; G11C 11/408; G11C 11/4091; H10B 12/00

(52) U.S. Cl. CPC G11C 5/063; G11C 11/4085; G11C 11/4091; H10B 12/09; H10B 12/482; H10B 12/488; H10B 12/50

(57) ABSTRACT

According to one aspect of the present disclosure, a memory device is provided. The memory device may include a first semiconductor structure including a memory cell array. The memory cell array may include a plurality of word lines extending in a first direction with each of the word lines connected to a word line connection structure at its middle location. The memory device may include a second semiconductor structure at least including a plurality of first control circuits and at least part of a peripheral circuit distributed in gaps between the plurality of first control circuits. The first semiconductor structure and the second semiconductor structure may be stacked and connected. The first control circuit may include a first sub-control circuit disposed in a first region and connected with the word line connection structure and a second sub-control circuit disposed in a second region and a third region.

### CROSS-REFERENCE TO RELATED APPLICATIONS

This application claims the benefit of priority to Chinese Application No. 202411392131.9, filed on Sep. 30, 2024, which is incorporated herein by reference in its entirety.

### TECHNICAL FIELD

Examples of the present disclosure relate to the field of semiconductor technology, and in particular to a memory device and a fabrication method thereof as well as a system.

### BACKGROUND

A memory device is a storage apparatus used for saving information in modern information technology. With the increasing demands for the storage apparatus, there is much room for improvement of the memory device.

### SUMMARY

According to one aspect of the present disclosure, a memory device is provided. The memory device may include a first semiconductor structure including a memory cell array. The memory cell array may include a plurality of word lines extending in a first direction with each of the word lines connected to a word line connection structure at its middle location. The memory device may include a second semiconductor structure at least including a plurality of first control circuits and at least part of a peripheral circuit distributed in gaps between the plurality of first control circuits. The first semiconductor structure and the second semiconductor structure may be stacked and connected. The first control circuit may include a first sub-control circuit disposed in a first region and connected with the word line connection structure and a second sub-control circuit disposed in a second region and a third region. The second region and the third region may be located at both sides of the first region in the first direction. The memory device may include a first interconnection layer located on a side of the second semiconductor structure away from the first semiconductor structure. The memory device may include a plurality of connection structures. Each of the plurality of connection structures may extend in a second direction in the second semiconductor structure and may have one end connected with the at least part of the peripheral circuit in the gaps and another end connected with the first interconnection layer. The second direction may be perpendicular to the first direction

In some implementations, the memory device may further include a second interconnection layer between the first semiconductor structure and the second semiconductor structure. In some implementations, the first semiconductor structure and the second semiconductor structure may be connected through the second interconnection layer.

In some implementations, the memory device may further include a third interconnection layer, a first bonding layer, a second bonding layer, and a fourth interconnection layer stacked between the first semiconductor structure and the second semiconductor structure. In some implementations, the first semiconductor structure and the second semiconductor structure may be connected through the third interconnection layer, the first bonding layer, the second bonding layer, and the fourth interconnection layer.

In some implementations, the middle location may be within a middle one-third section of the word line in the first direction.

In some implementations, two word line connection structures connected with two adjacent word lines may be staggered in a third direction. In some implementations, the third direction may intersect the first direction and may be perpendicular to the second direction.

In some implementations, the word line connection structure may extend in the second direction.

In some implementations, composition materials of the word lines may include a material whose resistivity is smaller than a preset resistivity.

In some implementations, the composition materials of the word lines may include molybdenum.

In some implementations, the memory cell array may include a plurality of banks each including a plurality of blocks. In some implementations, one of the first control circuits may be connected with one of the plurality of blocks and the peripheral circuit may be connected with each of the plurality of banks.

In some implementations, the second semiconductor structure may further include at least one of a plurality of second control circuits or a datapath circuit. In some implementations, one of the second control circuits may be connected with one of the banks. In some implementations, the at least one of the second control circuits or the datapath circuit may be distributed in the gaps between the plurality of first control circuits.

In some implementations, the at least part of the peripheral circuit may include a plurality of first portions and one second portion. In some implementations, at least one of the plurality of first portions or the second portion may be connected with the first interconnection layer through the plurality of connection structures. In some implementations, a region where one of the first portions and the first control circuit are connected correspondingly with one respective block are disposed may have a border overlapping with a border of a region where the respective block is disposed. In some implementations, a region where the second portion is disposed may have a border overlapping with borders of the gaps between adjacent blocks.

In some implementations, the first region may extend in a third direction. In some implementations, the second region and the third region may extend in the first direction. In some implementations, the third direction may intersect the first direction and may be perpendicular to the second direction. In some implementations, the first region may be located at the middle section in the first direction of the region where one of the first portions and the first control circuit may be correspondingly connected with one respective block are disposed.

In some implementations, a size in the third direction of a border of the first region may be smaller than or equal to a size in the third direction of a border of a region where the block is disposed. In some implementations, a sum of sizes in the first direction of a border of the first region and a border of the second and third regions may be the same as a size in the first direction of the border of the region where the block is disposed.

In some implementations, the first region may include a first sub-region and a second sub-region. In some implementations, the first sub-region and the second sub-region may be staggered along the third direction and the second region and the third region are staggered or aligned along the first direction.

In some implementations, the first sub-region may have the same size as the second sub-region and the second region has the same size as the third region.

In some implementations, the second region and third region where the second sub-control circuit is connected with two blocks adjacent in the third direction may be respectively disposed are located at the same or different corresponding locations in the respective blocks.

In some implementations, the first sub-control circuit may include a word line driver. In some implementations, the second sub-control circuit may include a sensing amplifier. In some implementations, the sensing amplifier may be connected with bit lines in a block.

In some implementations, the peripheral circuit may include at least one of a local control circuit for data lines, a data bus switching circuit, a data input/output circuit, a data input/output control circuit, a one-time programmable memory, a data error correction circuit, a row hammer defense circuit, a command buffer, a command decoder, an address buffer, a data buffer, or a mode register.

In some implementations, the second semiconductor structure may include a plurality of active regions spaced apart by an isolation region. In some implementations, the connection structures may be disposed at borders of the active regions and in the isolation region.

In some implementations, the memory device may further include power supply wiring and the power supply wiring may be disposed in the first interconnection layer.

In some implementations, the memory device further may include pads. In some implementations, the pads may be located on a side of the first interconnection layer away from the second semiconductor structure and may be electrically connected with the first interconnection layer.

In some implementations, the memory cell array may include a plurality of bit lines extending in a third direction. In some implementations, the memory cell array may include a plurality of semiconductor pillars arranged in an array and a plurality of memory structures each corresponding to one of the plurality of semiconductor pillars. In some implementations, a semiconductor pillar and its corresponding memory structure may be disposed in a stacking configuration. In some implementations, the semiconductor pillar may extend in a second direction and may have a first end and a second end disposed opposite to each other in the third direction. In some implementations, the first end may be connected with the bit line and the second end may be connected with the memory structure. In some implementations, the word line may be coupled to at least one side of the semiconductor pillar. In some implementations, the third direction may intersect the first direction and may be perpendicular to the second direction.

In some implementations, the memory device may include a three-dimensional NAND memory or a random access memory.

According to another aspect of the present disclosure, a method of fabricating a memory device is provided. The method may include forming a first semiconductor structure that may include a memory cell array including a plurality of word lines extending in a first direction. Each of the word lines may be connected to a word line connection structure at its middle location. The method may include forming a second semiconductor structure that includes a plurality of first control circuits and at least part of a peripheral circuit distributed in gaps between the first control circuits. The first semiconductor structure and the second semiconductor structure may be stacked and connected. The first control circuit may include a first sub-control circuit disposed in a first region and connected with the word line connection structure and a second sub-control circuit disposed in a second region and a third region. The second region and the third region may be located at both sides of the first region in the first direction. The method may include forming a first interconnection layer on a side of the second semiconductor structure away from the first semiconductor structure. The method may include forming a plurality of connection structures extending in a second direction in the second semiconductor structure. One end of the connection structure may be connected with the at least part of the peripheral circuit in the gaps and another end of the connection structure connected with the first interconnection layer. The second direction may be perpendicular to the first direction.

In some implementations, the forming the first semiconductor structure, the second semiconductor structure, and the first interconnection layer may include forming the second semiconductor structure on a first surface of a first substrate. In some implementations, the forming the first semiconductor structure, the second semiconductor structure, and the first interconnection layer may include forming a second interconnection layer on the second semiconductor structure. In some implementations, the forming the first semiconductor structure, the second semiconductor structure, and the first interconnection layer may include forming the first semiconductor structure on the second interconnection layer. In some implementations, the first semiconductor structure and the second semiconductor structure may be connected through the second interconnection layer. In some implementations, the forming the first semiconductor structure, the second semiconductor structure, and the first interconnection layer may include forming the first interconnection layer on a second surface of the first substrate. In some implementations, the first surface and the second surface may be two surfaces disposed opposite to each other in the second direction.

In some implementations, forming the first semiconductor structure may include forming a plurality of bit lines extending in a third direction. In some implementations, forming the first semiconductor structure may include forming a plurality of semiconductor pillars on the surface of the bit lines. In some implementations, the semiconductor pillars may extend in the second direction. In some implementations, forming the first semiconductor structure may include forming a plurality of word lines extending in the first direction. In some implementations, the word line may be located on at least one side of the semiconductor pillar, and the third direction may intersect the first direction and may be perpendicular to the second direction. In some implementations, forming the first semiconductor structure may include forming a memory structure on a surface of each of the semiconductor pillars away from the bit lines.

In some implementations, the method may further include providing a third substrate. In some implementations, the method may further include bonding the third substrate on the memory structures to form a bonded structure. In some implementations, the method may further include turning the bonded structure upside down to expose the second surface of the first substrate. In some implementations, the method may further include forming the first interconnection layer on the second surface of the first substrate and then removing the third substrate.

In some implementations, forming the first semiconductor structure, the second semiconductor structure, and the first interconnection layer may include forming the second semiconductor structure on a first surface of a first substrate. In some implementations, forming the first semiconductor structure, the second semiconductor structure, and the first interconnection layer may include forming a third interconnection layer and a first bonding layer that are stacked in this order on the second semiconductor structure. In some implementations, forming the first semiconductor structure, the second semiconductor structure, and the first interconnection layer may include forming the first semiconductor structure on a second substrate. In some implementations, forming the first semiconductor structure, the second semiconductor structure, and the first interconnection layer may include forming a fourth interconnection layer and a second bonding layer that are stacked in this order on the first semiconductor structure. In some implementations, forming the first semiconductor structure, the second semiconductor structure, and the first interconnection layer may include bonding the first bonding layer and the second bonding layer together. In some implementations, the first semiconductor structure and the second semiconductor structure may be connected through the third interconnection layer, the first bonding layer, the second bonding layer, and the fourth interconnection layer. In some implementations, forming the first semiconductor structure, the second semiconductor structure, and the first interconnection layer may include forming the first interconnection layer on a second surface of the first substrate. In some implementations, the first surface and the second surface may be two surfaces disposed opposite to each other in the second direction.

In some implementations, forming the first semiconductor structure may include forming a plurality of memory structures on the second substrate. In some implementations, forming the first semiconductor structure may include forming a semiconductor pillar on the surface of each of the memory structures away from the second substrate. In some implementations, the semiconductor pillar may extend in the second direction. In some implementations, forming the first semiconductor structure may include forming a plurality of word lines extending in the first direction. In some implementations, the word line may be located on at least one side of the semiconductor pillar. In some implementations, forming the first semiconductor structure may include forming a bit line on the surface of the semiconductor pillar away from the memory structure. In some implementations, the bit line may extend in a third direction, and the third direction may intersect the first direction and may be perpendicular to the second direction.

According to a further aspect of the present disclosure, a memory system is provided. The memory system may include a memory device. The memory device may include a first semiconductor structure including a memory cell array. The memory cell array may include a plurality of word lines extending in a first direction with each of the word lines connected to a word line connection structure at its middle location. The memory device may include a second semiconductor structure including a plurality of first control circuits and at least part of a peripheral circuit distributed in gaps between the plurality of first control circuits. The first semiconductor structure and the second semiconductor structure may be stacked and connected. The first control circuit may include a first sub-control circuit disposed in a first region and connected with the word line connection structure and a second sub-control circuit disposed in a second region and a third region. The second region and the third region may be located at both sides of the first region in the first direction. The memory device may include a first interconnection layer located on a side of the second semiconductor structure away from the first semiconductor structure. The memory device may include a plurality of connection structures. Each of the plurality of connection structures may extend in a second direction in the second semiconductor structure and may have one end connected with the at least part of the peripheral circuit in the gaps and another end connected with the first interconnection layer. The second direction may be perpendicular to the first direction.

### BRIEF DESCRIPTION OF DRAWINGS

FIG. 1 is a structural diagram illustrating a configuration of an example dynamic random access memory in an example of the present disclosure;

FIG. 2 is a first top view illustrating the distribution of a memory cell array and a peripheral circuit of an example memory device in an example of the present disclosure;

FIG. 3A is a second top view illustrating the distribution of a memory cell array and a peripheral circuit of an example memory device in an example of the present disclosure;

FIG. 3B is a specific example expansion view based on FIG. 3A in an example of the present disclosure;

FIG. 3C is an example enlarged view based on the region PZ in FIG. 3A in an example of the present disclosure;

FIG. 4A is a third top view illustrating the distribution of a memory cell array and a peripheral circuit of an example memory device in an example of the present disclosure;

FIG. 4B is a fourth top view illustrating the distribution of a memory cell array and a peripheral circuit of an example memory device in an example of the present disclosure;

FIG. 5A is an example enlarged view based on the region QZ in FIG. 4A or FIG. 4B in an example of the present disclosure;

FIG. 5B is an example enlarged view based on the region RZ in FIG. 5A in an example of the present disclosure;

FIG. 5C is an example schematic diagram based on a block in FIG. 5A with an enlarged size in an example of the present disclosure;

FIG. 6A is a first cross section of a memory device in an example of the present disclosure;

FIG. 6B is a first schematic diagram illustrating a connection between a word line connection structure and a word line provided in an example of the present disclosure;

FIG. 6C is a second cross section of a memory device provided in an example of the present disclosure;

FIG. 6D is a second schematic diagram illustrating a connection between a word line connection structure and a word line provided in an example of the present disclosure;

FIG. 7 is a third cross section of a memory device provided in an example of the present disclosure;

FIGS. 8A to 8E are planar views illustrating an arrangement of first control circuits corresponding to blocks in several memory devices provided in examples of the present disclosure;

FIGS. 9A to 9C are planar views illustrating an arrangement of word lines, word line connection structures and bit lines in several memory devices provided in examples of the present disclosure;

FIG. 10A is a first planar view illustrating an arrangement of the memory cell array of a memory device provided in an example of the present disclosure;

FIG. 10B is a cross section taken along the cutting plane C-C in FIG. 10A;

FIG. 11A is a second planar view illustrating an arrangement of the memory cell array of a memory device provided in an example of the present disclosure;

FIG. 11B is a cross section taken along the cutting plane C-C in FIG. 11A;

FIG. 12A is a third planar view illustrating an arrangement of the memory cell array of a memory device provided in an example of the present disclosure;

FIG. 12B is a cross section taken along the cutting plane C-C in FIG. 12A;

FIG. 13A is a first planar view illustrating an arrangement of memory structures of a memory device provided in an example of the present disclosure;

FIG. 13B is a second planar view illustrating an arrangement of memory structures of a memory device provided in an example of the present disclosure;

FIG. 14 is a flow chart illustrating a method of fabricating a memory device provided in an example of the present disclosure;

FIGS. 15A to 15K are first cross sections in a process of forming a memory device provided in an example of the present disclosure; and

FIGS. 16A to 16D are second cross sections in a process of forming a memory device provided in an example of the present disclosure.

### DETAILED DESCRIPTION

The technical solutions in implementations of the present disclosure will be described below clearly and completely in connection with implementations and accompanying drawings of the present disclosure. It is obvious that the described implementations are only some, not all, implementations of the present disclosure. All other implementations obtained by those skilled in the art based on implementations of the present disclosure without any creative works fall within the scope claimed by the present disclosure.

In the description hereafter, many specific details are provided to facilitate a more thorough understanding of the present disclosure. However, it is apparent for those skilled in the art that the present disclosure can be implemented without one or more of these details. In other examples, in order not to obscure the present disclosure, some technical features well known in the art will not be described. That is to say, not all features of practical examples will be described herein and well-known functions and structures will not be described in detail.

In accompanying drawings, dimensions and relative sizes of layers, regions and elements may be exaggerated for clearance. The same reference numerals refer to the same elements throughout the specification.

It should be appreciated that when an element or a layer is said to be “over”, “adjacent to”, “connected to” or “coupled to” another element or layer, it may be directly over, adjacent to, connected to or coupled to the other element or layer or an intervening element or layer may exist therebetween. On the contrary, when an element is said to be “directly on”, “directly adjacent to”, “directly connected to” or “directly coupled to” another element or layer, there is no intervening element or layer therebetween. It should be appreciated that although various elements, components, regions, layers and/or parts may be described using terms “first”, “second”, “third” or the like, they are not limited by those terms. The terms are only used to distinguish one element, component, region, layer or part from another element, component, region, layer or part. Therefore, a first element, component, region, layer or part discussed hereafter may be instead expressed as a second element, component, region, layer or part without departing from the teaching of the present disclosure. When a second element, component, region, layer or part is in discussion, it is not intended to indicate that a first element, component, region, layer or part must exist in the present disclosure.

Spatially relative terms, such as “below”, “beneath”, “lower”, “under”, “over” and “above”, are used herein for ease of description to explain the relationship of one element or feature with other elements or features as shown in the figures. It should be appreciated that, in addition to the orientations shown in the figures, different orientations of devices in use and operation are also intended to be covered by those spatially relative terms. For example, if a device is turned upside down in the figure, the element or feature described to be “beneath”, “under” or “below” another element or feature will have the orientation of being “over” the other element or feature. Therefore, example terms “beneath” and “under” may include orientations of both “below” and “above”. Devices may be otherwise oriented (rotated 90 degrees or at other orientations) and the spatially relative descriptors used herein may likewise be interpreted accordingly.

Terminology is used herein only for description of examples and in no way for limiting the present disclosure. As used herein, the terms “a”, “an” and “said/the” in singular forms are also intended to cover their plural forms, unless the context clearly indicates otherwise. It is also be appreciated that terms “comprise”, “comprising”, “include” and/or “including”, as used in the specification, specify presence of the mentioned features, integers, steps, operations, elements and/or components, but do not exclude presence or addition of one or more other features, integers, steps, operations, elements, components and/or combinations thereof. As used herein, the term “and/or”includes any and all combinations of relevant listed items.

For a thorough understanding of the present disclosure, detailed steps and structures will be provided in the following description to set forth the solutions of the present disclosure. Detailed description of the examples of the present disclosure is as follows, however the present disclosure may have other implementations in addition to the detailed description.

Memory devices involved in examples of the present disclosure may be a three-dimensional NAND memory, a random access memory (RAM) such as a dynamic random access memory (DRAM), a synchronous DRAM (SDRAM), a static RAM (SRAM), a double data rate SDRAM (DDR SDRAM), a DDR2 SDRAM, a DDR3 SDRAM, a phase change RAM (PRAM), a magnetic RAM (MRAM), a resistive RAM (RRAM) or a ferroelectric RAM (FRAM). Only a DRAM is taken as an example for the following description.

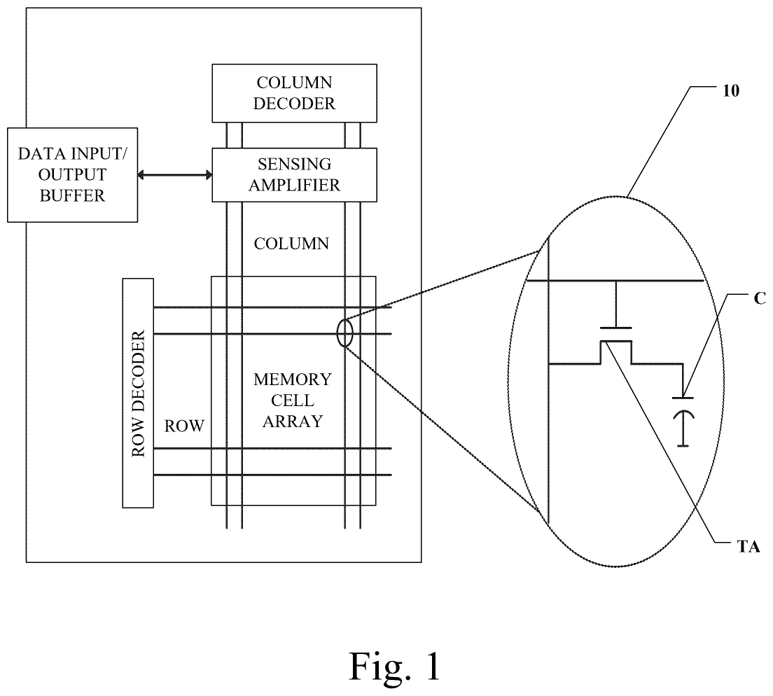

FIG. 1 is a structural diagram illustrating a configuration of an example dynamic random access memory in an example of the present disclosure.

A schematic circuit of a memory cell in a DRAM is shown on the right side in FIG. 1. The DRAM includes at least one DRAM die and each DRAM die includes a memory cell array including a plurality of memory cells 10 arranged in an array. Each memory cell 10 includes an array transistor TA and a capacitor C and functions mainly with the principle of representing a binary bit of 1 or 0 by the amount of the charge stored in the capacitor. The memory cells are arranged in an array and may be considered as a typical grid structure. The memory cell array specifies addresses using rows and columns. The memory controller can access individual memory cells in the DRAM die independently and perform read, write or refresh operation on the data stored therein by designating intersections of rows and columns (by designating row addresses and column addresses).

The memory cell array, word lines (rows), bit lines (columns), part of a control circuit and part of a peripheral circuit in the DRAM are illustrated on the left side in FIG. 1. It is to be noted that a row decoding circuit in the control circuit selects a word line and thus the row of memory cells to be accessed in response to the address input to the row decoding circuit. The row decoding circuit decodes the input address and enables (activates) the word line corresponding to the decoded address. A column decoding circuit in the control circuit selects one or more bit lines to input the data output by the user to a part of the row of memory cells corresponding to the selected word line.

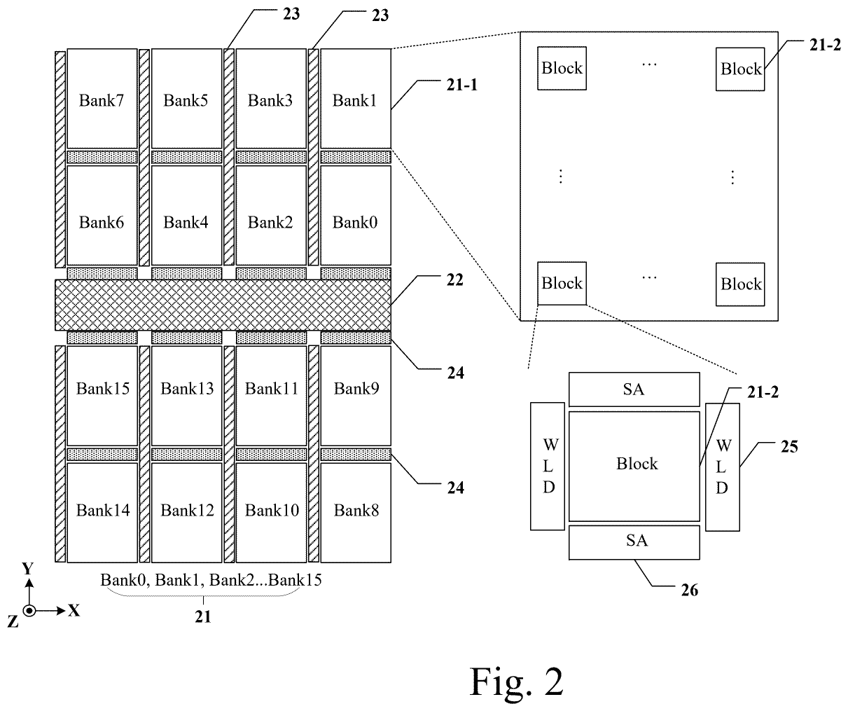

FIG. 2 is a first top view illustrating the distribution of the memory cell array and the peripheral circuit of an example memory device in an example of the present disclosure. One of the arrangements of the memory device will be detailed hereafter in connection with FIG. 2. Before introduction of the memory device illustrated in FIG. 2, the directions that may be used in the following description are defined first. Two intersecting directions parallel to the plane of the substrate (or a semiconductor structure) are defined as a first direction (e.g., the X direction) and a third direction (e.g., the Y direction). The direction perpendicular to the plane of the substrate (or the semiconductor structure) is defined as a second direction (e.g., the Z direction). If associating these directions to the structures in the memory device, then the first direction is the extending direction of the word lines, the third direction is the extending direction of the bit lines, and the second direction is perpendicular to both the extending direction of the word lines and extending direction of the bit lines. In some examples, any two directions among the X direction, Y direction and Z direction may be perpendicular to each other.

As shown in FIG. 2, the memory cell array 21 and the peripheral circuit 22 are disposed side by side. Further, in some examples, the memory cell array 21 includes a plurality of banks 21-1 (Bank0-Bank15) (e.g., 16 banks) and each bank 21-1 includes a plurality of memory blocks 21-2, with a sensing amplifier (SA) 26 and a word line driver (WLD) 25 corresponding to each block 21-2 disposed on four sides of that block, a column decoding circuit 24 and a row decoding circuit 23 corresponding to each bank disposed on two sides of that bank, a bank row formed by each multiple (e.g. 4) banks, and the peripheral circuit 22 corresponding to all the banks disposed between the two middle bank rows. It is to be noted that the number of the banks and the position relationship between the circuits in FIG. 2 are only for example and not used to exert any limitation on the number of the banks and the position relationship between the circuits in the memory devices in the present disclosure.

Here and hereafter, the peripheral circuit 22 is the control circuit corresponding to all the banks. In other words, all the banks share the peripheral circuit 22. The peripheral circuit 22 may include, but is not limited to, a local control circuit for data lines, a data bus switching circuit, a data input/output circuit, a data input/output control circuit, a one-time programmable memory, a data error correction circuit, a row hammer defense circuit, a command buffer, a command decoder, an address buffer, a data buffer, a mode register and the like. In some examples, the peripheral circuit may further include an analog circuit and a logic circuit. Here, the analog circuit may include, but is not limited to, an amplifier, a signal operation and processing circuit, an oscillating circuit, a modulation and demodulation circuit, a voltage converter and the like, and the logic circuit may include various circuits for logic operations of digital signals. A first control circuit is the control circuit corresponding to the block, such as the above-described SA and WLD. That is, each block corresponds to a set of a SA and a WLD, which may all be disposed next to the respective block in consideration of the convenience of wiring. A second control circuit is the control circuit corresponding to the bank, such as the above-described column decoding circuit and row decoding circuit. That is, each bank corresponds to a set of a column decoding circuit and a row decoding circuit, which may all be disposed next to the corresponding bank in consideration of the convenience of wiring.

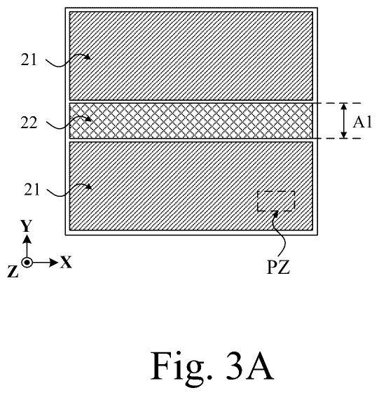

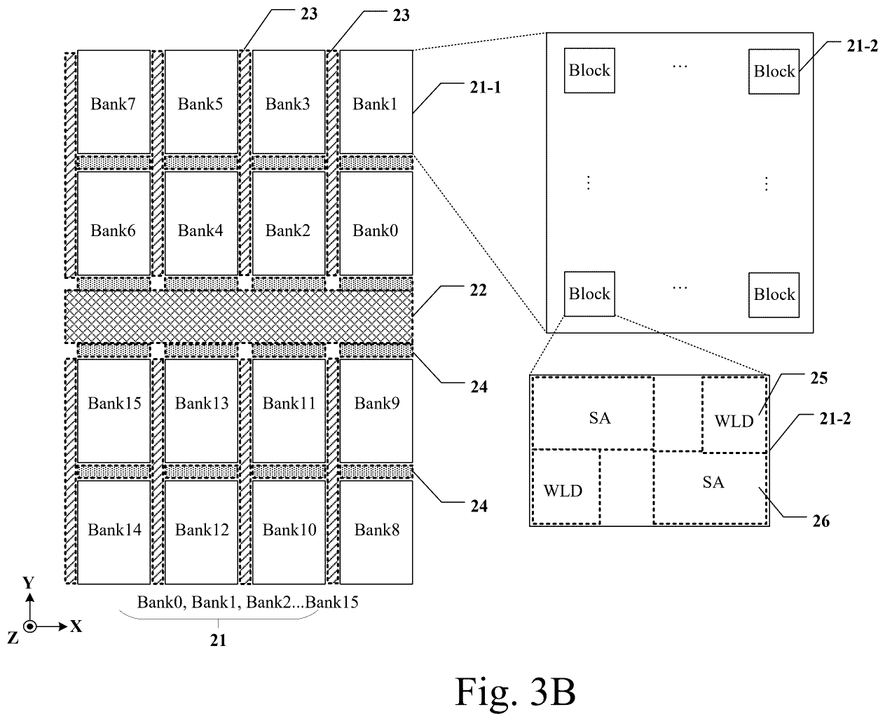

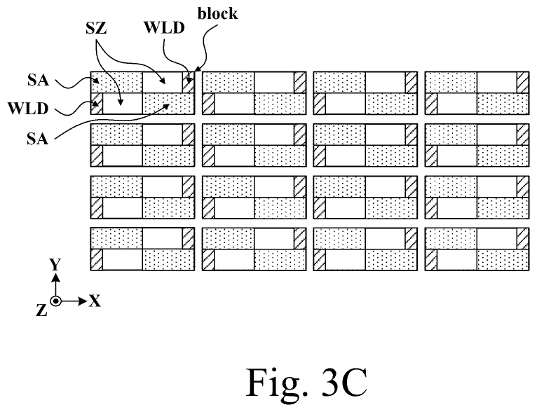

FIG. 3A is a second top view illustrating the distribution of the memory cell array and the peripheral circuit of an example memory device in an example of the present disclosure; FIG. 3B is a specific example expansion view based on FIG. 3A in an example of the present disclosure; and FIG. 3C is an example enlarged view based on the region PZ in FIG. 3A in an example of the present disclosure.

With reference to FIGS. 3A and 3B, the memory device may be a structure that includes a first semiconductor structure including a memory cell array and a second semiconductor structure including a peripheral circuit with the first semiconductor structure and the second semiconductor structure stacked in the Z direction. Here, FIG. 3B is different from FIG. 2 in that the SA 26 and WLD 25 of each block 21-2 are all disposed below each block. Based on this, in the enlarged view corresponding to each block 21-2 in FIG. 3B, the solid lines represent the enlarged portion of the block 21-2 and the dashed lines represent the SA 26 and WLD 25 corresponding to and directly below the block 21-2. It is to be noted that in some other examples, positions of the block 21-2 and the SA 26 and WLD 25 corresponding to the block 21-2 may be exchangeable up and down. Description will be provided only with the case in which the SA 26 and the WLD 25 are located below the block 21-2, taken as an example.

In FIG. 3A, the peripheral circuit 22 corresponding to all the banks are disposed on the second semiconductor structure. For convenience of routing, the middle region between the two memory cell arrays 21 disposed on the first semiconductor structure may be spare, e.g., have no device placed therein, and the peripheral circuit 22 on the second semiconductor structure may be directly seen from a top view.

The region PZ in FIG. 3A is identified by dashed lines, and it can be seen that FIG. 3C shows the regions that are directly below 16 blocks 21-2 and corresponding to regions for disposing the SAs 26 and WLDs 25 corresponding to the blocks 21-2. For example, the block0 corresponds to a SA located in two regions and a WLD located in two regions. In FIG. 3C, a plurality of SAs 26 and a plurality of WLDs 25 arranged in an array corresponding to a plurality of blocks 21-2 arranged in an array are illustrated.

In the example above, the SAs and WLDs corresponding to the respective blocks may be arranged directly below the respective blocks without occupying additional chip area. However, the peripheral circuit described above is arranged outside the orthogonal projection of the memory arrays on the plane of the second semiconductor structure (an X-Y plane) and occupy additional area.

In the example above, in consideration of the relatively large area occupied by the peripheral circuits, if the peripheral circuits are placed dispersedly in separate regions spaced from each other, the wiring for interconnection lines of the peripheral circuits may be complex and this complex routing may conflict with the wirings for the first control circuits and the second control circuits. As a result, the control circuits are centralized on the second semiconductor structure, and then the area on the first semiconductor structure corresponding to the peripheral circuits is substantially vacant and wasted. With the increasingly improved integrity of complementary metal oxide semiconductor (CMOS), the area occupied by the first control circuits is reduced and the area occupied by the first control circuit corresponding to each block is smaller than the area occupied by the block, so there are some spare regions under the block except those for arrangement of the first control circuit and the area of the spare regions is considerable. Based on this, the spare regions may be stitched together reasonably through arrangement planning to form a relatively large region for placement of at least part of the peripheral circuit.

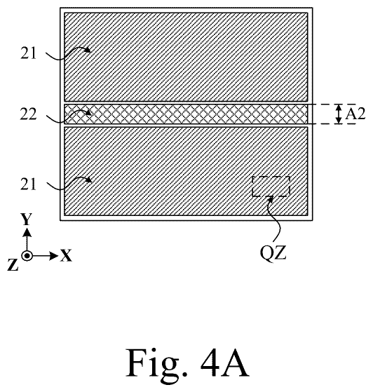

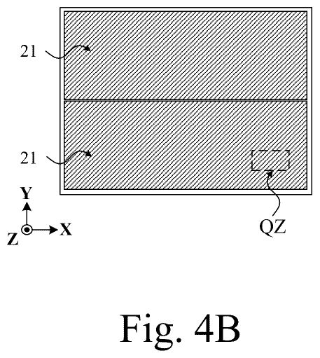

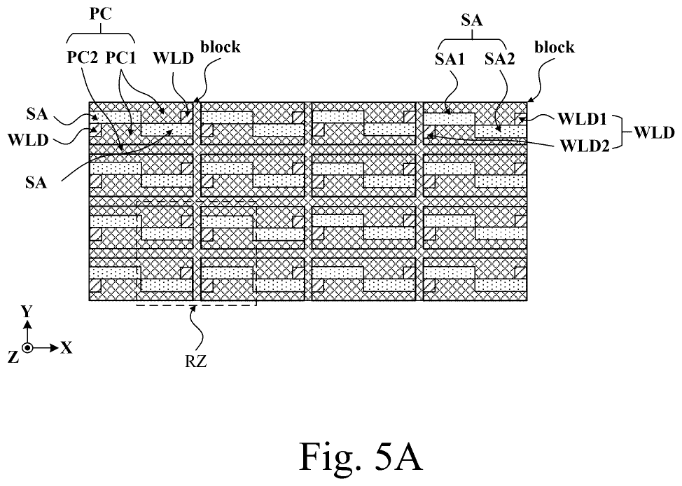

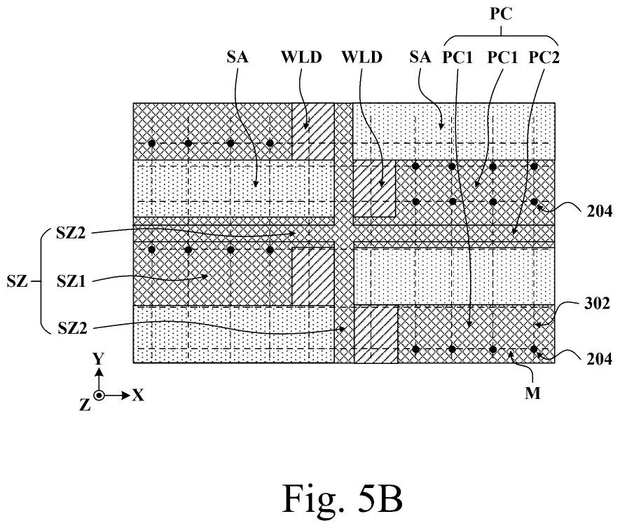

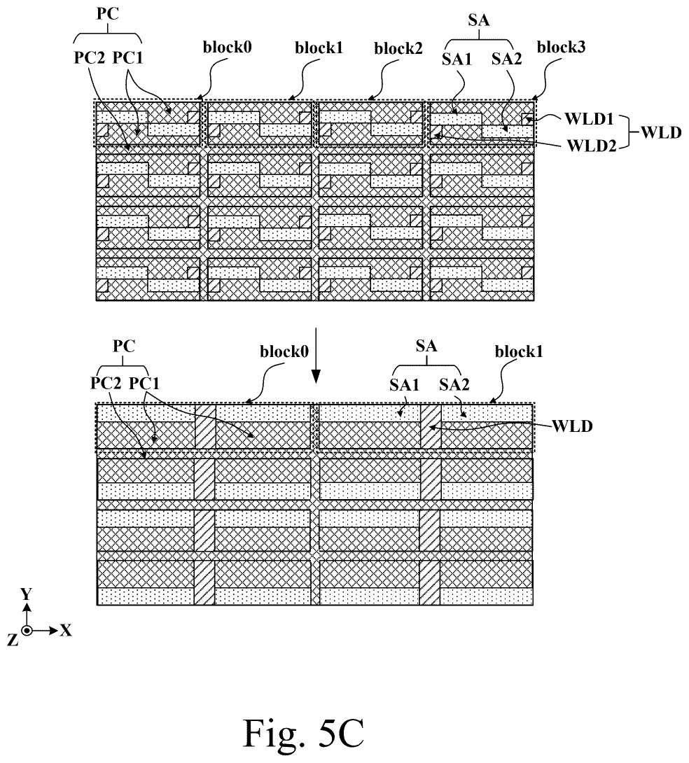

FIG. 4A is a third top view illustrating the distribution of the memory cell array and the peripheral circuit of an example memory device in an example of the present disclosure, and FIG. 4B is a fourth top view illustrating the distribution of the memory cell array and the peripheral circuit of an example memory device in an example of the present disclosure. FIG. 5A is an example enlarged view based on the region QZ in FIGS. 4A and 4B in an example of the present disclosure; FIG. 5B is an example enlarged view based on the region RZ in FIG. 5A in an example of the present disclosure; and FIG. 5C is an example schematic diagram based on a block in FIG. 5A with an enlarged size in an example of the present disclosure.

In some examples, with reference to FIGS. 4A and 4B and FIGS. 5A and 5B, in comparison with the memory device shown in FIGS. 3A to 3C, a memory device is provided, in which at least part of the peripheral circuit may be placed reasonably utilizing the above-mentioned spare regions to directly reduce the additional area occupied by the peripheral circuit; at the same time, for the second semiconductor structure having the peripheral circuits and the first control circuits formed on its front side, the lines connecting the first control circuits to the memory cell array are arranged on the front side of the second semiconductor structure, and the lines connecting the respective peripheral circuits dispersed at the gaps between the locations of the first control circuits are arranged on the back side of the second semiconductor structure, so that conflicts in wiring between the two types of lines can be avoided and in turn the purpose of saving area can be achieved while maintaining the same storage capacity and control circuit performance.

The memory device in FIG. 3A may serve as a contrast to the memory device in FIGS. 4A and 4B. It can be understood that in the memory device in FIGS. 4A and 4B, under the premise of unchanged storage capacity of the memory device, the spare regions below the blocks in the memory device in FIG. 3A are directly utilized or larger spare regions below the blocks obtained after size reduction of the first control circuits are utilized to place at least part of the peripheral circuit. In FIG. 4A, part of the peripheral circuit is placed in the spare regions and the remaining part of the peripheral circuit not placed in the spare regions has a size A2 in the Y direction smaller than the size A1 of the corresponding peripheral circuit in the Y direction in FIG. 3A; while in FIG. 4B, the entire peripheral circuit is placed in the spare regions, e.g., the entire peripheral circuit is placed below the memory cell array. It is to be noted that in some other examples, positions of the block and the SA and WLD corresponding to that block and the peripheral circuit at the spare regions may be exchangeable up and down. By way of example and not limitation, the description will be provided only with the case in which the SA, WLD, and the peripheral circuit at the spare regions are located below the blocks.

With FIG. 3C as a contrast, in FIG. 5A, it can be understood that there is a plurality of SAs, a plurality of WLDs arranged in an array and part of the peripheral circuit PC corresponding to a plurality of blocks arranged in an array. It is to be noted that in contrast to FIG. 3C, the first control circuit in FIG. 5A has a reduced size and area, so that there are larger spare regions below each block for placement of at least part of the peripheral circuit PC.

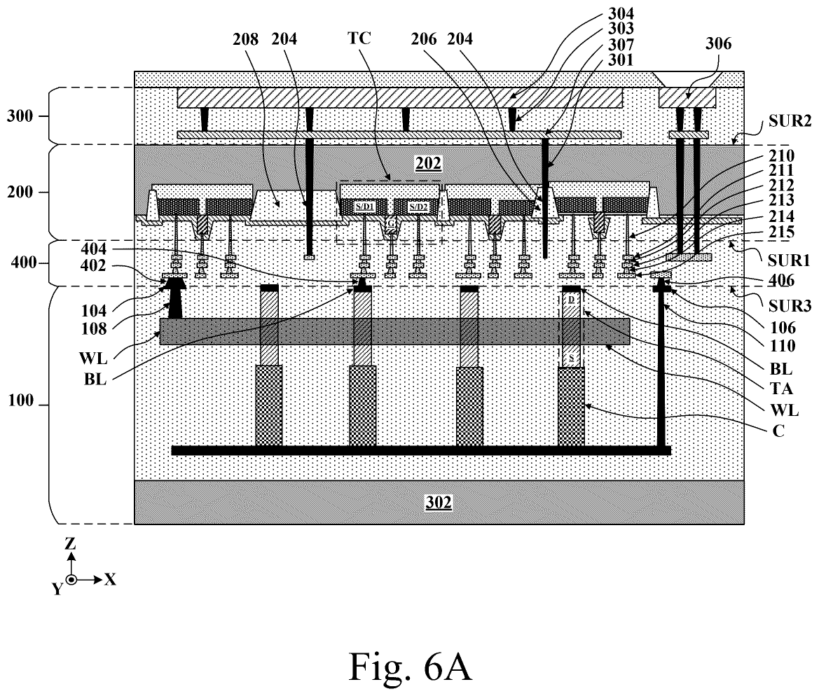

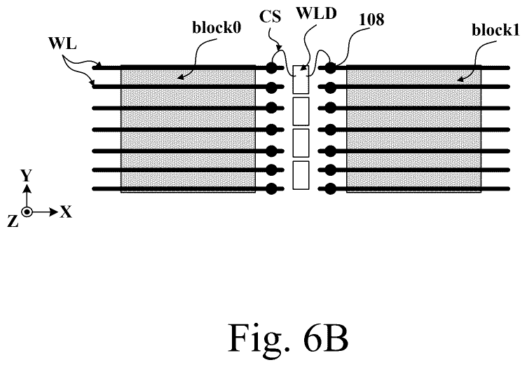

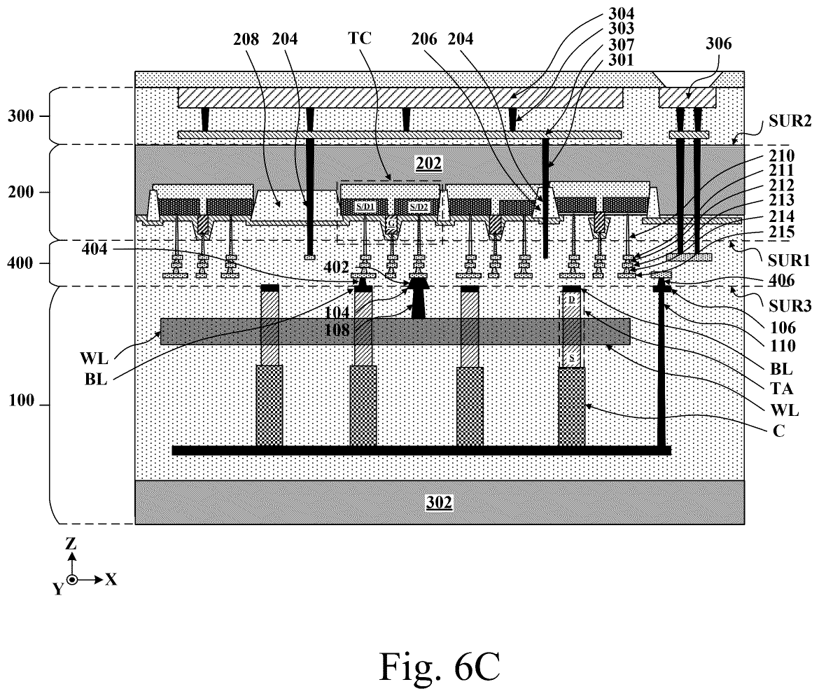

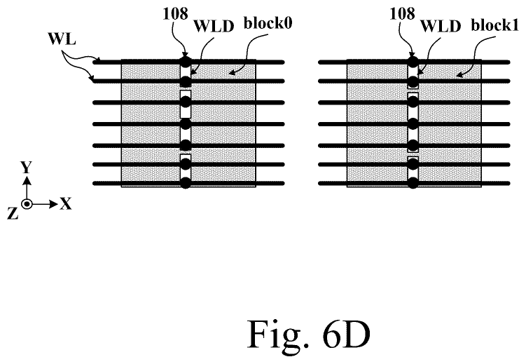

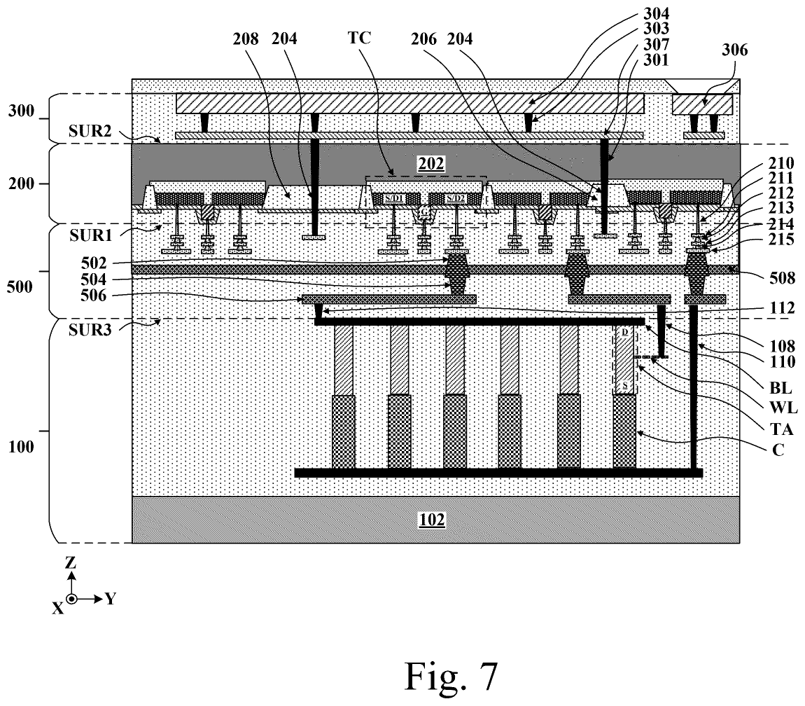

FIG. 5B shows the wiring (e.g., the metal layer 307 of Layer 3 in FIGS. 6C and 7) on the back side of the second semiconductor structure with dashed lines through perspective, and also shows through-silicon contacts (TSCs) (e.g., the connection structures 204 in FIGS. 6C and 7) with solid dots. It is to be noted that the relationship between positions and number of the back-side wiring and the TSCs in FIG. 5B are only an example and are not used to exert any limitation on the relationship between positions and the number of the back-side wiring and the TSCs in the memory devices in the present disclosure.

With reference to FIG. 5B, the back-side wiring is connected with at least part of the peripheral circuit through TSCs, e.g., at least part of the peripheral circuit in the spare regions are connected utilizing the back-side wiring and the TSCs, and this connecting wiring does not conflict with the front-side wiring for the first control circuit on the front side of the second semiconductor structure.

With reference to FIG. 5B, in some examples, the lines for metal interconnection in the back-side wiring of the second semiconductor structure may be used for arrangement of a power bus; since this power bus may be nearer to the wiring for the peripheral circuit, the power source may have a very low voltage drop and a very high utilization ratio. Meanwhile, on the back side of the second semiconductor structure, the metal layers for interconnection of peripheral circuit and the metal layers for arrangement of the power bus may share part of the metal layers, so that the total number of the metal layers on the front side and the back side can be lowered and in turn the processing cost can be reduced.

It has been mentioned above that in contrast to FIG. 3C, the first control circuit in FIG. 5A has a reduced size and area, so that each memory array has a larger spare area to accommodate at least a portion of the peripheral circuit PC. However, when each block has a relatively small size, the region below each block that can be used to arrange at least part of the peripheral circuit PC will be piecemeal and irregular. In FIG. 5C, the size of the block in the figure below the arrow is larger than the size of the block (e.g., 2 times the size of the block) in the figure above the arrow, and as such, the region below each block that can be used to arrange at least part of the peripheral circuit PC will be more regular and have better integrity, so that the peripheral circuit PC can be placed below the block more flexibly to optimize PC arrangement, put more PCs, and reduce the overall size of the memory device. At the same time, the reduction in size can provide more room for integration of computation units and memory cells, so that the time for data transmission can be reduced to improve performance and allow the possibility of in-memory computing, integrated memory and computing.

How to increase the size of the block in a memory device will be described in detail hereafter. It is to be noted that the above-mentioned factor in FIG. 5C, by which the size of a block is increased, is only for illustration and not used to limit examples of the present disclosure with respect to the specific value of change in size of a block, and no specific case of the increase in size of a block will be defined in examples of the present disclosure.

In a first aspect, with reference to FIGS. 6C and 7, examples of the present disclosure provide a memory device that includes: a first semiconductor structure including a memory cell array, where the memory cell array includes a plurality of word lines extending in a first direction with each word line connected to a word line connection structure at its middle location. The memory device may include a second semiconductor structure at least including a plurality of first control circuits and at least part of a peripheral circuit distributed at gaps between the plurality of first control circuits, where the first semiconductor structure and the second semiconductor structure are stacked and connected. The first control circuit includes a first sub-control circuit disposed in a first region and connected with the word line connection structure and a second sub-control circuit disposed in a second region and a third region, with the second region and the third region located at both sides of the first region in the first direction. The memory device may include a first interconnection layer located on a side of the second semiconductor structure away from the first semiconductor structure. The memory device may include a plurality of connection structures, each of which extends in a second direction in the second semiconductor structure and has one end connected with the at least part of the peripheral circuit at the gaps and another end connected with the first interconnection layer. The second direction may be perpendicular to the first direction. As described herein, the first direction may also be understood as the extending direction of the word lines WL and be represented as the X direction in the figures, the third direction may also be understood as the extending direction of the bit lines BL and be represented as the Y direction in the figures, and the second direction may be understood as the direction, along which the first semiconductor structure and the second semiconductor structure are stacked, and be represented as the Z direction in the figures.

It is to be noted that the cross section shown in FIG. 6C is a cross section formed by the extending direction of the word lines of a memory device and the direction along which the first semiconductor structure and the second semiconductor structure are stacked and may be represented as an X-Z cross section in the figure; the cross section shown in FIG. 7 is a cross section formed by the extending direction of the bit lines of another memory device and the direction along which the first semiconductor structure and the second semiconductor structure are stacked and may be represented as a Y-Z cross section in the figure.

It is to be noted that the components, circuits, devices, etc. are labelled with the same reference number in circuits of FIGS. 6C and 7 can be understood as the same or similar components, circuits, devices, etc.

The first semiconductor structure 100 may include a memory cell array. Each memory cell in the memory cell array can be understood with reference to the description about the memory cells in FIG. 1. The capacitor C may be formed in a planar configuration, a layered configuration or a trench configuration depending on the fabrication method. The capacitor C may be coupled to the first doped region (e.g., the source region S) of an array transistor TA to be charged or discharged through the first doped region. The memory cell array may also include word lines and bit lines. The word line WL may be coupled to a gate of the array transistor TA to turn on or turn off the array transistor TA. The bit line BL may be coupled to the second doped region (e.g., the drain regions D) of the array transistor TA and act as the path for charging and discharging of the capacitor C.

The second semiconductor structure 200 may include the first control circuit and at least part of the peripheral circuit. The first control circuit and the peripheral circuit may include any suitable analog, digital, and mixed-signal circuit to facilitate operations of the memory cell array by applying and sensing voltage signals and/or current signals to and from each target memory cell through the bit lines and word lines. The first control circuit and the peripheral circuit may include various types of circuits formed using the MOS technology. Both the first control circuit and the at least part of the peripheral circuit may include a plurality of peripheral transistors TC to form a control circuit configured to perform operations on the memory cell array, for example, to perform writing or reading on memory cells of the memory cell array.

In some examples, the memory cell array includes a plurality of banks each including a plurality of blocks. One first control circuit is connected with one block, and a peripheral circuit is connected with the plurality of banks. In examples of the present disclosure, the first control circuit is the control circuit corresponding to the block, and the first control circuit may include a first sub-control circuit and a second-sub control circuit to perform various functions. In some examples, the first sub-control circuit may include a word line driver WLD and the second sub-control circuit may include a sensing amplifier SA.

The SA is configured to sense a low-power signal from the bit line that represents a data bit (1 or 0) stored in the DRAM memory cell and amplify a small voltage swing to an identifiable logic level. This enables a logic outside the DRAM memory device to output data correctly. The WLD may be configured to apply respective driving voltages to the word lines that select/deselect the blocks.

It can be understood that at least one of the length of the word line or the length of the bit line will be increased after the size of the block is increased in the memory device; since the signal received by the SA will become weaker due to the increased length of the bit line and this will exert obvious influence on the memory device, consideration will be mainly focused on the increased length of the word line in examples of the present disclosure. Given a certain driving capability of the WLD, the influence by the increased length of the word line can be canceled by reducing the resistance from the word line to the WLD.

In examples of the present disclosure, the increased size of the block can be supported by reasonably disposing the location, at which the word line connection structure is connected with the corresponding word line. In examples of the present disclosure, the word line connection structure is disposed at a middle location of the word line. In some examples, the middle location is within the middle one-third section of the word line in the first direction. In some implementations, the middle location is the geometric center of the word line in the first direction.

Here, compared to the case in which the word line connection structure is disposed at an edge of the word line, disposing the word line connection structure at the middle location of the word line may reduce the RC from the most distant end of the word line through the word line connection structure to the first sub-control circuit. If the word line connection structure is disposed at the center of the word line, the RC from the most distant end of the word line through the word line connection structure to the first sub-control circuit may be reduced to half of the original value, and theoretically, the size of the block can be increased to 2 times of the original size.

In examples of the present disclosure, by selecting a material for the word line reasonably (e.g., by selecting a material with relatively low resistivity for the word line), the resistance of the word line can remain unchanged as the length of the word line increases so as to support the increased size of the block.

Based on this, in some examples, the composition material for the word line includes a material with a resistivity smaller than a preset resistivity. Here, the preset resistivity may be 5.3×10⁻⁸ Ω·m@20° C. In some implementations, the composition material for the word line includes molybdenum (Mo). The resistivity of molybdenum is 5.2×10⁻⁸ Ω·m@20° C.

The above-described solutions supporting an increased size of the block may be used in combination, so that the size of the block can be further increased.

In examples of the present disclosure, the word line connection structure is disposed at the middle location of the word line, and the locations where the SA and WLD are arranged are adjusted, e.g., such that the first region where the WLD is arranged is disposed in the middle of the second region where the SA is arranged and the third region. In examples of the present disclosure, the region where both the word line connection structure and the WLD are arranged are disposed at the location proximate to the middle of the respective structures, which can facilitate direct connection between them in the second direction. In some examples, the word line connection structure extends in the second direction.

FIG. 6A is a first cross section of a memory device provided in an example of the present disclosure; FIG. 6B is a first schematic diagram illustrating a connection between a word line connection structure and a word line provided in an example of the present disclosure; FIG. 6C is a second cross section of a memory device provided in an example of the present disclosure; and FIG. 6D is a second schematic diagram illustrating a connection between a word line connection structure and a word line provided in an example of the present disclosure.

Referring to FIGS. 6A and 6B, the word line connection structure 108 is located at an edge of the word line. In FIG. 6B, the WLDs are located at a projection in a Z-axis direction of a gap between two blocks adjacent in the first direction, and the word line connection structure 108 is connected with the WLD through a connection line CS.

In FIGS. 6C and 6D, the word line connection structure 108 is located at the middle location of the word line. In FIG. 6D, the WLD is located at the middle location of the projection in the Z-axis direction of the respective block, and the middle location may cover the projection in the Z-axis direction of the word line connection structure 108 on the word line. The word line connection structure 108 may be directly connected with the WLD. It can be seen from comparison that disposing the region where the word line connection structure and the WLD are arranged at the location proximate to the middle of the respective structure may facilitate direct connection therebetween, reduce additional impedance caused by routing, and thus, further reduce the resistance between the word line and the first sub-control circuit. As previously described, the peripheral circuit is the control circuit corresponding to all the banks. In other words, all the banks share the peripheral circuit. In some examples, the peripheral circuit may include, but is not limited to, a local control circuit for data lines, a data bus switching circuit, a data input/output circuit, a data input/output control circuit, a one-time programmable memory, a data error correction circuit, a row hammer defense circuit, a command buffer, a command decoder, an address buffer, a data buffer, a mode register and the like. In some examples, the peripheral circuit may further include analog circuits and logic circuits. Here, the analog circuits may include, but are not limited to, an amplifier, a signal operation and processing circuit, an oscillating circuit, a modulation and demodulation circuit, a voltage converter and the like, and the logic circuits may include various circuits for logic operations of digital signals.

It is to be noted that part of the peripheral circuit or the entire peripheral circuit are dispersedly arranged at the gaps between the plurality of first control circuits corresponding to the plurality of blocks included by the bank. If the part of the peripheral circuit is disposed at the gaps of the first control circuits, the remaining of the peripheral circuit will be arranged as a whole at one side of the bank.

In some examples, the second semiconductor structure 200 includes a first substrate 202 and a peripheral transistor TC on a front side of a second substrate. In some examples, the first substrate 202 may include a silicon (Si) substrate, a germanium (Ge) substrate, a silicon germanium (SiGe) substrate or the like and may also be silicon on insulator (SOI) or germanium on insulator (GOI). In some examples, impurity ions can be doped into the first substrate 202 as needed, the impurity ions may be N-type impurity ions or P-type impurity ions. The doping includes doping of a well region and doping of a source/drain region. In some examples, the peripheral transistor TC may include a NMOS transistor formed in P well and a PMOS transistor formed in N well. A plurality of peripheral transistors TC are connected to each other through a metal interconnection layer to form the first control circuit and at least part of the peripheral circuit.

In some examples, the front-side metal interconnection layer may be a metal interconnection layer on a side of the first substrate 202 having a peripheral transistor thereon, e.g., the side proximate to the first surface SUR1 (or the front side) of the second semiconductor structure 200. The front-side metal interconnection layer may include contacts and metal interconnection lines. In some examples, the front-side metal interconnection layer includes a plurality of metal layers and a plurality of contacts stacked alternately and connected with each other. In some examples, the front-side metal interconnection layer may have three stacked layers including a Layer 0 contact 210, a Layer 0 metal layer 211, a Layer 1 contact 212, a Layer 1 metal layer 213, a Layer 2 contact 214 and a Layer 2 metal layer 215 that are stacked sequentially. Here, the plurality of metal layers includes the Layer 0 metal layer 211, the Layer 1 metal layer 213, and the Layer 2 metal layer 215, and the plurality of contacts includes the Layer 0 contact 210, the Layer 1 contact 212 and the Layer 2 contact 214. The Layer 0 contact 210 extends and is coupled to the first source/drain S/D1 or the second source/drain S/D2 of the peripheral transistor TC, or extends to the gate G of the peripheral transistor TC. Materials for the contacts and the metal interconnection lines may include, but are not limited to, tungsten, cobalt, nickel, copper, aluminum, polysilicon, doped silicon, silicide, nitride, or any combination thereof.

A first interconnection layer 300 is located on a side of the second semiconductor structure 200 away from the first semiconductor structure 100 and can be understood as a back-side metal interconnection layer, which may be a metal interconnection layer formed on the second surface SUR2 (or known as the back side) of the second semiconductor structure 200 and includes contacts and metal interconnection lines.

In some examples, the back-side metal interconnection layer includes a plurality of metal layers and a plurality of contacts stacked alternately and connected with each other. In some examples, the back-side metal interconnection layer may have two stacked layers including a Layer 3 contact 301, a Layer 3 metal layer 307, a Layer 4 contact 303, and a Layer 4 metal layer 304 that are stacked sequentially. Here, the plurality of metal layers includes the Layer 3 metal layer 307 and the Layer 4 metal layer 304, and the plurality of contacts includes the Layer 3 contact 301 and the Layer 4 contact 303. The Layer 3 contact 301 (that may be understood as the connection structure 204) extends and is coupled to the front-side metal interconnection layer. For example, the Layer 3 contact 301 extends and is coupled to the Layer 0 metal layer 211. In some examples, the material used for the Layer 3 metal layer 307 may be the same or different than the material used for the Layer 4 metal layer 304. In some examples, the material for the Layer 4 metal layer 304 may include aluminum or an aluminum alloy, and the material for the Layer 3 metal layer 307 may include copper or a copper alloy.

The connection structure 204 extends through part of the second semiconductor structure 200 and has one end connected with the at least part of the peripheral circuit at the gaps and the other end connected with the first interconnection layer 300. The connection structure 204 may extend through the first substrate 202. The connection structure 204 may have one end extending to the front-side metal interconnection layer to be connected with the at least part of the peripheral circuit in the second semiconductor structure 200. The other end of the connection structure 204 may extend to the back-side metal interconnection layer to be connected with the first interconnection layer 300. For example, the two ends of the connection structure 204 may extending through the first substrate 202 may extend to the Layer 3 metal layer 307 and the Layer 0 metal layer 211, respectively.

In some examples, an isolation region is also disposed on the front side of the second substrate. In the isolation region, a first insulation structure 206 spacing a plurality of active regions in the first substrate 202 apart from each other or a second insulation structure 208 spacing a plurality of well regions (P wells/N wells) in the first substrate 202 apart from each other may be disposed. The first insulation structure 206 and the second insulation structure 208 in the first substrate 202 may be obtained through a shallow trench isolation (STI) process. The materials for the first insulation structure 206 and the second insulation structure 208 include, but are not limited to, silicon oxide, silicon nitride, silicon oxynitride or any combination thereof.

The following description may be referred to for details about the connection between the first semiconductor structure 100 and the second semiconductor structure 200.

In examples of the present disclosure, the first semiconductor structure and the second semiconductor structure are stacked, which can substantially improve the storage density of the memory device. Using the back-side wirings of the second semiconductor structure and the connection structures connected to the at least part of the peripheral circuit, the at least part of the peripheral circuit may be dispersedly arranged below the blocks of the memory cell array so that the area occupied by the peripheral circuit in the second semiconductor structure is directly reduced. The routing of the back-side wirings of the second semiconductor structure may enable interconnection between the at least part of the peripheral circuit arranged dispersedly without any conflict with the front-side wirings of the second semiconductor structure.

With reference to FIG. 6C, in some examples, the memory device further includes a second interconnection layer between the first semiconductor structure and the second semiconductor structure. The first semiconductor structure and the second semiconductor structure are connected through the second interconnection layer. The second interconnection layer 400 may be a metal interconnection layer formed at the first surface SUR1 (or known as the front side) of the second semiconductor structure 200 and at a third surface SUR3 (the third surface SUR3 may be understood as a surface of the first semiconductor structure 100 proximate to the first surface SUR1) of the first semiconductor structure 100. The second interconnection layer 400 may include a single-layered interconnection layer or a multi-layered interconnection layer including, for example, the above-described Layer 0 contact 210, Layer 0 metal layer 211, Layer 1 contact 212, Layer 1 metal layer 213, Layer 2 contact 214 and Layer 2 metal layer 215 that are stacked sequentially, the second interconnection layer 400 as well as the word line contacts 402, the bit line contacts 404, etc. The materials for the word line contacts 402 and the bit line contacts 404 may include, but are not limited to, tungsten, cobalt, nickel, copper, aluminum, polysilicon, doped silicon, silicide, nitride, or any combination thereof. In some examples, the second interconnection layer further includes a capacitor common electrode contact 406. The materials for the capacitor common electrode contact 406 includes, but are not limited to, tungsten, cobalt, nickel, copper, aluminum, polysilicon, doped silicon, silicide, nitride or any combination thereof.

It is to be noted that in the example shown in FIG. 6C, the first semiconductor structure and the second semiconductor structure are connected only through the second interconnection layer therebetween. A third substrate 302 is a substrate that functions as a carrier rather than a base for growth and can be selectively removed. That is, in the example show in FIG. 6, both the first semiconductor structure and the second semiconductor structure are formed through growth by using the first substrate 202 as a base. In this way, the use of the growth substrate and manufacturing code may be reduced.

With reference to FIG. 7, in some examples, the memory device further includes a third interconnection layer, a first bonding layer, a second bonding layer, and a fourth interconnection layer stacked between the first semiconductor structure and the second semiconductor structure. The first semiconductor structure and the second semiconductor structure are connected through the third interconnection layer, the first bonding layer, the second bonding layer, and the fourth interconnection layer.

As used herein, the third interconnection layer, the first bonding layer, the second bonding layer and the fourth interconnection layer may be abbreviated as a bonding interconnection structure 500. The bonding interconnection structure 500 includes contacts and metal interconnection lines.

The third interconnection layer and the first bonding layer may be metal interconnection layers (including contacts and metal interconnection lines) formed on the first surface SUR1 (or the front side) of the second semiconductor structure 200. The third interconnection layer may include a single-layered interconnection layer or a multi-layered interconnection layer including, for example, the above-described Layer 0 contacts 210, Layer 0 metal layer 211, Layer 1 contacts 212, Layer 1 metal layer 213, Layer 2 contacts 214, and Layer 2 metal layer 215 that are stacked sequentially. The first bonding layer may include first bonding contacts 502. The fourth interconnection layer and the second bonding layer may be metal interconnection layers (including contacts and metal interconnection lines) formed on the third surface SUR3 of the first semiconductor structure 100. The fourth interconnection layer may include a single-layered or a multi-layered interconnection layer including, for example, the Layer 5 metal layer 506. The second bonding layer may include second bonding contacts 504. The bonding interconnection structure 500 having a bonding interface 508 may be obtained by bonding the second semiconductor structure 200 having the first bonding contacts 502 and the first semiconductor structure 100 having the second bonding contacts 504 through a hybrid bonding process. The first bonding contacts 502 and the second bonding contacts 504 are in contact and electrically connected with each other.

In the example shown in FIG. 7, the first semiconductor structure and the second semiconductor structure may be connected through bonding. The first substrate 202 is used as the growth substrate for the second semiconductor structure 200 and the second substrate 102 is used as the growth substrate for the first semiconductor structure 100. That is, in the example shown in FIG. 7, the first semiconductor structure and the second semiconductor structure are grown on different substrates respectively. Thus, the problem of mutual constraints between the fabrication procedures of the memory cell array and the peripheral circuit may be solved to shorten the development period of the memory device.

In some examples, at least part of the peripheral circuit includes a plurality of first portions and one second portion. At least one of the plurality of first portions or the second portion are connected with the first interconnection layer through the plurality of connection structures.

In some examples, the memory cell array may include a plurality of banks, for example, 16 banks. The number of the banks may be more or fewer than 16. Each bank may include a plurality of blocks, for example, 16 blocks. The number of the blocks may be more or less than 16.

In some examples, with reference to FIG. 5B, the spare region SZ may include a first spare region SZ1 located in the projection region under the block except for the region where the first control circuit is disposed. The spare region SZ may further include a second spare region SZ2 located in the projection region under the gap between adjacent blocks. The number of the first spare regions SZ1 is the same as the number of the blocks contained in the memory cell array.

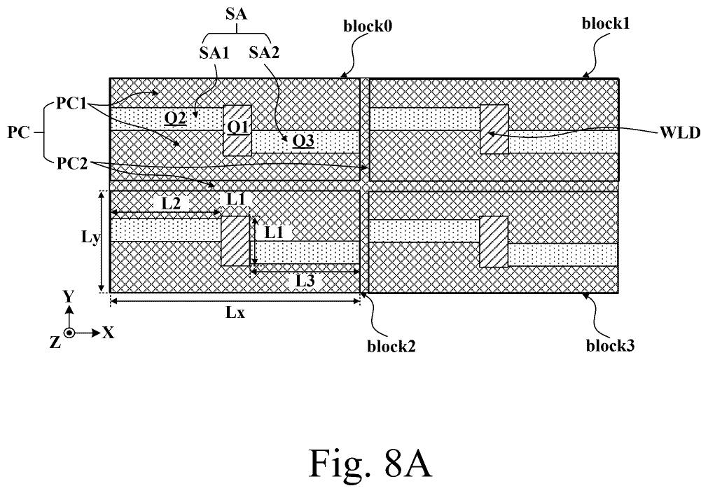

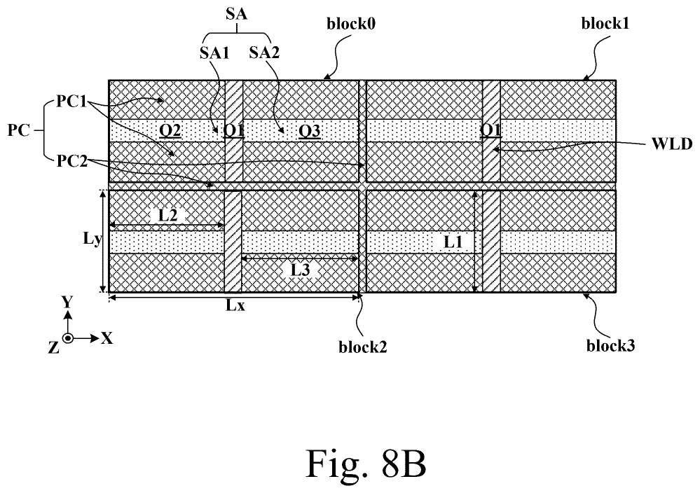

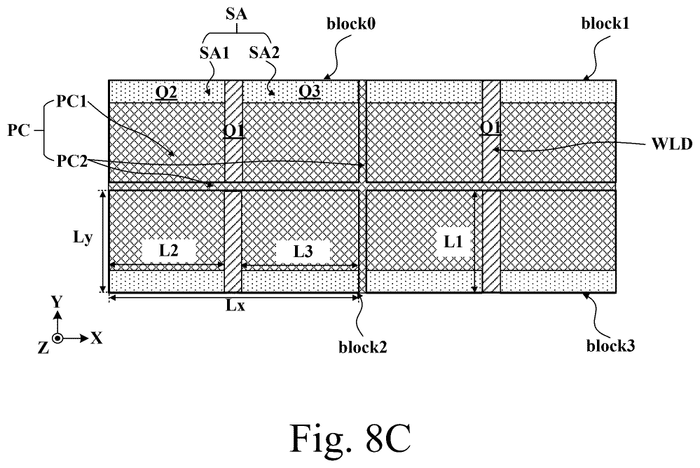

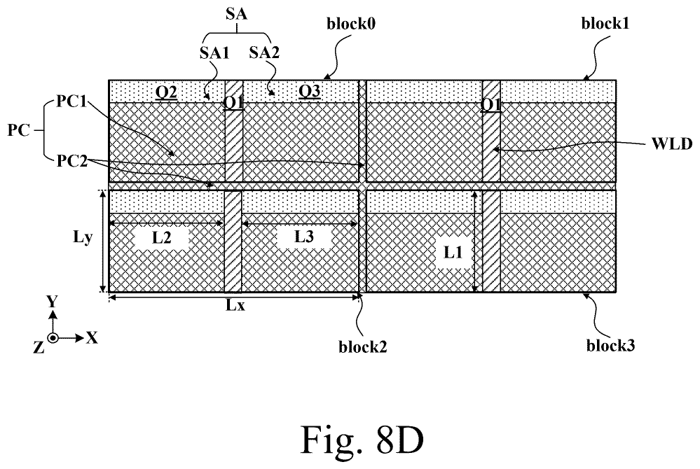

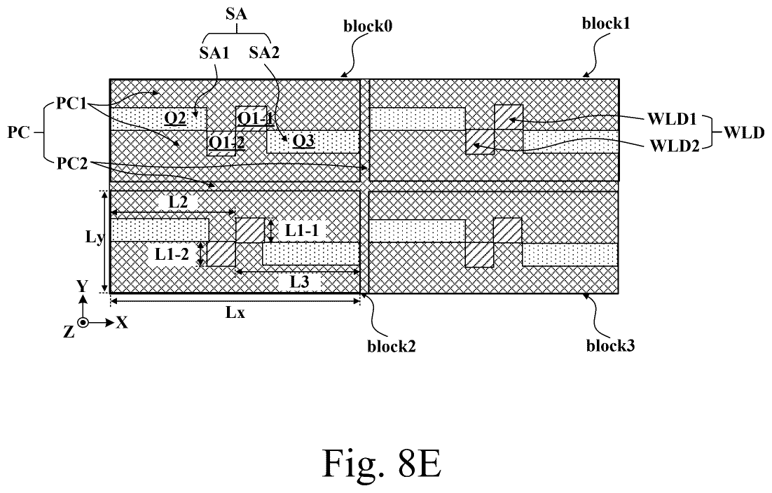

The at least part of the peripheral circuit PC includes a plurality of first portions PC1 (FIG. 5B shows two first portions PC1) in the first spare region SZ1 and one second portion PC2 in the second spare region SZ2. FIG. 5B shows two first portions PC1 are located below blocks and spaced from each other and one second portion PC2 is located as a whole below the location between adjacent blocks. The two first portions PC1 and the one second portion PC2 are both connected to the first interconnection layer through the plurality of connection structures 204. It is to be noted that the arrangement of the first control circuit in FIGS. 5A and 5B is only an example, and the following FIGS. 8A and 8B show more examples of the arrangement of the first control circuit. It can be understood that these examples are only used to understand and exemplify the arrangement of the first control circuit in the examples of the present disclosure rather than to limit the arrangement of the first control circuit in the examples of the present disclosure.

With reference to FIGS. 6C and 7, in some examples, the first sub-control circuit includes a word line driver and the second sub-control circuit includes a sensing amplifier. The word line driver is connected with the word lines in the block and the sensing amplifier is connected with the bit lines in the block. The first direction is perpendicular to the extending direction of the bit lines and the third direction is perpendicular to the extending direction of the word lines.

With reference to FIG. 6C, in some examples, the first semiconductor structure 100 may include the memory cell array and the first control circuit of the second semiconductor structure 200 may include the word line driver and sensing amplifier. Here, the word line WL in the memory cell array may be connected with the word line driver through the word line contact 402, and the bit line BL in the memory cell array may be connected with the sensing amplifier through the bit line contact 404. In some examples, the word line WL may be connected with the word line contact 402 through the word line connection structure 108, a word line landing pad 104. Additionally, the capacitor C may be connected with a capacitor common electrode contact 406 through a capacitor connection structure 110 and/or a capacitor landing pad 106.

With reference to FIG. 7, in some examples, the first semiconductor structure 100 may include the memory cell array and the first control circuit of the second semiconductor structure 200 may include a word line driver and a sensing amplifier. Here, the word line WL in the memory cell array may be connected with the word line driver through the bonding interconnection structure 500, and the bit line BL in the memory cell array may be connected with the sensing amplifier through the bonding interconnection structure 500. In some examples, the word line WL, the bit line BL, and the capacitor C in the memory cell array of the first semiconductor structure 100 may be respectively connected to the Layer 5 metal layer 506 of the bonding interconnection structure 500 through the word line connection structure 108, the bit line connection structure 112, and the capacitor connection structure 110. Then, the word line WL, the bit line BL, and the capacitor C in the memory cell array of the first semiconductor structure 100 may be connected to the plurality of second bonding contacts 504 and the plurality of first bonding contacts 502 of the bonding interconnection structure 500 through the Layer 5 metal layer 506 of the bonding interconnection structure 500. Finally, the word line WL, the bit line BL, and the capacitor C in the memory cell array of the first semiconductor structure 100 may be connected to the word line driver and the sensing amplifier in the second semiconductor structure 200 respectively through the plurality of first bonding contacts 502.

In some examples, at least one of the word line connection structures 108 or the bit line connection structures 112 may be located directly below the blocks.

The locations of the first sub-control circuit (e.g., the SA) and the second sub-control circuit (e.g., the WLD) within the corresponding region below the block (e.g., the orthogonal projection region of the block in the Z direction) may be adjusted as practically beneficial. The locations of the first sub-control circuit and the second sub-control circuit are arranged mainly in consideration of the convenience of connection with the word lines and bit lines in the block. Meanwhile, the corresponding region below the block should not be divided into regions too piecemeal because regions that are too piecemeal will increase the difficulty of arranging the peripheral circuit in the gaps between the first control circuits. It can be understood that disposing the SA and WLD corresponding to the block in the corresponding region (the projection region) directly below that block may reduce the total length from the bit line to the wiring of the sensing amplifier may reduce the coupling effects and increase the sensing window, while at the same time improving the voltage drop caused by long distance routing between the word line driver and the word lines.

FIGS. 8A to 8E are planar views illustrating arrangements of the first control circuit corresponding to the block in several memory devices provided in examples of the present disclosure. Example arrangements of the first sub-control circuit (WLD) and the second sub-control circuit (SA) in the corresponding region below the block will be introduced in detail in connection with FIGS. 8A to 8E hereafter.

It is to be noted that each of FIGS. 8A to 8E shows an example arrangement of the first sub-control circuits and the second sub-control circuits of the first control circuits corresponding respectively to four adjacent blocks having gaps therebetween (e.g., block0, block1, block2 and block3) in the projection regions directly below the respective blocks. The first sub-control circuits and the second sub-control circuits of the four blocks are arranged in the same way or in a symmetrical way. That is, in each arrangement, all the blocks have their first sub-control circuits and the second sub-control circuits arranged in the same way or in a symmetrical way. The first sub-control circuit WLD is arranged in a first region Q1 and the second sub-control circuit SA is divided into two portions SA1 and SA2 with SA1 arranged in a second region Q2 and SA2 arranged in a third region Q3. Except for those used to arrange the SAs and WLDs, the remaining regions in the projection regions directly below the four blocks may all be used to arrange the peripheral circuit.

In some examples, a region where one first portion PC1 and the first control circuit (SA+WLD) connected correspondingly with one respective block are disposed has a border overlapping with a border of a region where the respective block is disposed. A region where the second portion is disposed has a border overlapping with borders of the gaps between adjacent blocks.

Each first control circuit shown in FIGS. 8A to 8E is located within the orthogonal projection region of its corresponding block in the Z direction. That is, the orthogonal projection in the Z direction of the border of the region where a block is disposed accommodates one first portion PC1 and the first control circuit (SA+WLD) connected correspondingly with that block so that the number of the first portions is the same as the number of the blocks. The orthogonal projection in the Z direction of the borders of the gaps between all the blocks contained in the memory cell array accommodates a second portion PC2, and the regions where the second portion PC2 is disposed at the respective gaps join into a whole piece and are in contact with the regions where the first portions PC1 are disposed respectively.

In some examples, the first region extends in the third direction, and the second region and the third region extend in the first direction. The third direction intersects the first direction and is perpendicular to the second direction. The first region is located at the middle section in the first direction of the region where one first portion and the first control circuit correspondingly connected with one respective block are disposed.

In examples of the present disclosure, the region where each sub-control circuit is disposed may be configured according to the structural feature to be connected in the first semiconductor structure.

In FIGS. 8A to 8E, the first sub-control circuit may include a word line driver WLD that may be connected with a plurality of word lines in the first semiconductor structure. The plurality of word lines all extend in the first direction and are arranged side by side in the third direction. The word line driver WLD is connected with the plurality of word lines respectively through a plurality of conductive structures. When the region where the sensing amplifier is disposed extends in the third direction, relatively short conductive structures (e.g. perpendicular to regions for the word lines and the word line driver) can be used to connect the word line driver with the word lines, so that better wiring for connection can be achieved and in turn the voltage drop caused by long distance routing between the word line driver and the word lines can be improved.

In FIGS. 8A to 8E, the second sub-control circuit may include a sensing amplifier SA that may be connected with a plurality of bit lines in the first semiconductor structure. The plurality of bit lines all extend in the third direction and are arranged side by side in the first direction. The sensing amplifier SA is connected with the plurality of bit lines respectively through a plurality of conductive structures. When the regions for arrangement of the sensing amplifier extend in the first direction, relatively short conductive structures (e.g., perpendicular to regions for the bit lines and the sensing amplifier) may be used to connect the sensing amplifier with the bit lines. In this way, improved wiring for connection may be achieved, and the coupling effects caused by long distance routing between the sensing amplifier and the bit lines can be improved, increasing the sensing window.

As such, the first sub-control circuit and the second sub-control circuit having different functions in the first control circuit are separated and arranged in regions extending in different directions to adapt to different requirements for the connection between different sub-control circuit and the first semiconductor structure, enabling better wiring for connection and reducing adverse effects caused by long distance routing.

Here, the middle section is within the middle one-third section of the orthogonal projection region along the Z direction of the border of the region where one block is disposed. In some implementations, the first region is located at the central section in the first direction of the region where one first portion and the first control circuit connected correspondingly with one respective block are disposed, e.g., the first region is at the same distance from the borders in the first direction of the region where one first portion and the first control circuit connected correspondingly with one respective block are disposed. In examples of the present disclosure, the word line connection structures and the WLD are both disposed in the middle of the respective structures, which can facilitate direct connection between them in the second direction. In some examples, the word line connection structures extend in the second direction.

In some examples, the size in the third direction of the border of the first region is smaller than or equal to the size in the third direction of the border of the region where the block is disposed; the sum of the sizes in the first direction of the border of the first region and the border of the second and third regions is the same as the size in the third direction of the border of the region where the block is disposed.

Referring to FIG. 8A, the size L1′ in the third direction of the border of the first region Q1 is smaller than the size Ly in the third direction of the border of the region where the block is disposed; and the sum of the size L1 in the first direction of the border of the first region Q1, the size L2 in the first direction of the border of the second region, and the size L3 in the first direction of the border of the third region, e.g., (L1+L3+L4), is equal to the size Lx in the first direction of the border of the region where the block is disposed. In FIG. 8A, the second region Q2 and the third region Q3 may be in diagonal symmetry along the first region.

It is to be noted that other cases not shown in FIG. 8A are also included in the scope claimed by examples of the present disclosure. In some examples, the second region Q2 and the third region Q3 are moved in the Y direction (e.g., the example of the second region Q2 and the third region Q3 as shown in FIGS. 8B-8D). In some other examples, the first region Q1 is moved in the Y direction, or moved in the X direction by a small distance (but still within the middle section).

In some implementations, when the size L1′ in the third direction of the border of the first region Q1 is smaller than the size Ly in the third direction of the border of the region where a block is disposed, the word line connection structures connected to a portion of the word lines (a portion of the word lines whose projections in the Z axis located outside the projection of the first region Q1 in the Z axis) extend in the Z axis and are connected to the Q1 through connection lines extending in a direction parallel to the plane formed by the X axis and the Y axis.

With reference to FIGS. 8B-8D, the size L1′ in the third direction of the border of the first region Q1 is the same as the size in the third direction of the border of the region where the block is disposed. It is to be noted that other cases not shown in FIGS. 8B-8D are also included in the scope claimed by examples of the present disclosure. For example, the locations of at least one of the second region Q2 or the third region Q3 are moved in the Y direction arbitrarily or parallelly. For another example, the locations of the second region Q2 and the third region Q3 are not in symmetrical.

In some implementations, when the size L1′ in the third direction of the border of the first region Q1 is equal to the size Ly in the third direction of the border of the region where the block is disposed, the word line connection structures of all the word lines extend in the Z axis and may be directly connected to the Q1.

It is to be noted that no bit lines are disposed at the locations corresponding to the projection of the first region on the block to reduce the risk of connecting any word line connection structure to the bit line. At this point, the sum of the sizes in the first direction of the border of the first region and the border of the second and third region being the same as the size in the third direction of the border of the region where the block is disposed can ensure maximization of the number of the bit lines that can be disposed.

In some examples, the first region includes a first sub-region and a second sub-region, which are staggered along the third direction; the second region and the third region are staggered or aligned along the first direction.

With reference to FIG. 8, the first region includes a first sub-region Q1-1 and a second sub-region Q1-2, which are staggered along the third direction. It can be understood that when the first sub-region Q1-1 and the second sub-region Q1-2 are aligned in the third direction, they are merged into one region, as shown in FIGS. 8A-8D. FIG. 8E also shows the case in which the second region Q2 and the third region Q3 are staggered along the first direction. The term “staggered” here can be understood to mean that the projections in the Y direction of the second region Q2 and the third region Q3 do not completely overlap; for example, they can partially overlap or do not overlap at all. In some implementations, the first sub-region Q1-1 and the second region Q2 may share a common vertex and the second sub-region Q1-2 and the third Q3 may share a common vertex.

It is to be noted that other cases not shown in FIG. 8E are also included in the scope of the present disclosure. For example, there is a gap between the first sub-region Q1-1 and the second sub-region Q1-2 in the Y direction or there is some overlap between the first sub-region Q1-1 and the second sub-region Q1-2 in the X direction. In another example, the location of the first sub-region Q1-1 is switched to the left parallelly and the location of the second sub-region Q1-2 is switched to the right parallelly; and corresponding adjustments are selectively made to the second region Q2 and the third region Q3, for example, the second region Q2 and the third region Q3 move arbitrarily downwards in the Y direction.

FIGS. 8B-8D show the cases in which the second region Q2 and the third region Q3 are aligned in the first direction. The term “aligned” here may be understood to mean that the projections in the Y direction of the second region Q2 and the third region Q3 overlap completely. It is to be noted that the first sub-region Q1-1 and the second sub-region Q1-2 in FIG. 8E may be translated to FIGS. 8B-8D correspondingly. At this point, it can be considered that the second region Q2 and the third region Q3 in FIGS. 8B-8D are adjusted correspondingly in size, for example, their sizes in the X direction are reduced and their sizes in the Y direction are increased.

In some examples, the two second regions and third regions where the second sub-control circuits connected with two blocks adjacent in the third direction are disposed respectively, are located at the same or different corresponding locations in the respective blocks.

Referring to FIGS. 8A, 8B, 8D, and 8E, the two second regions and third regions where the second sub-control circuits connected with two blocks adjacent in the third direction are disposed respectively, are located at the same locations in the respective blocks; with reference to FIG. 8C, the two second regions and third regions where the second sub-control circuits connected with two blocks adjacent in the third direction are disposed respectively, are located at the different locations in the respective blocks.

In some examples, the first sub-region and the second sub-region are of the same size and the second region and the third region are of the same size. As such, the circuit layout and the wiring are more uniform and adverse consequence caused by differentiations can be avoided, which at the same time can provide simplification of the fabrication process to some extent.

In some examples, the border of the second region and the border of the third region are in contact with the two borders of the first region that are opposite to each other in the first direction. As such, the space can be fully utilized, so that the circuit layout of the first control circuit can be more compact and at the same time a larger mass of space can be reserved for the peripheral circuit.

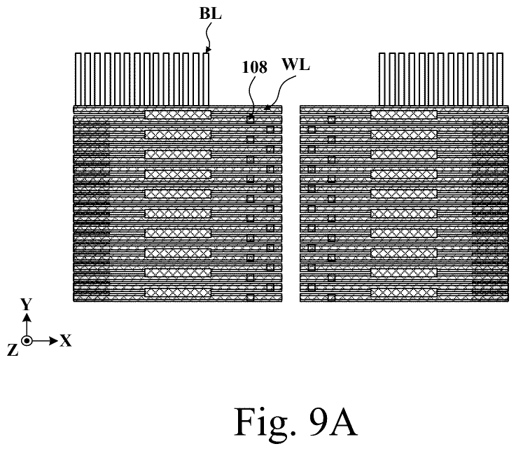

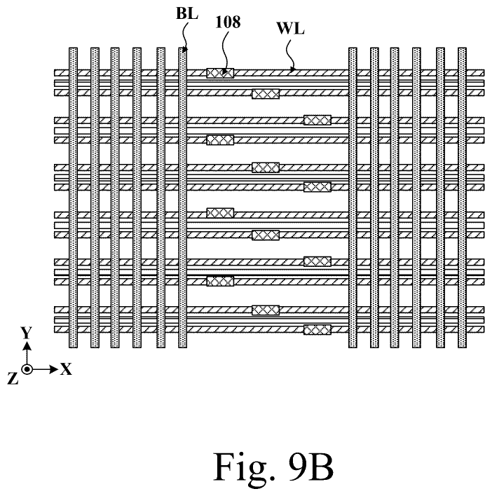

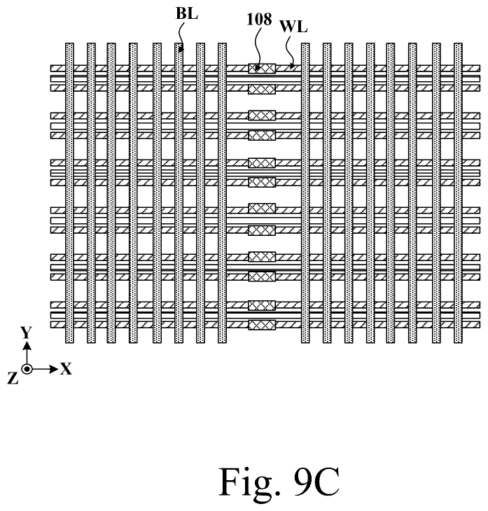

FIGS. 9A to 9C are planar views illustrating arrangements of the word lines, word line connection structures and bit lines in several memory devices provided in examples of the present disclosure. Specific arrangements of the word lines, word line connection structures and bit lines will be introduced in detail with reference to FIGS. 9A to 9C hereafter.

FIG. 9A shows the case in which the word line connection structures 108 are located at edges of the word lines WL. FIGS. 9B and 9C show the cases in which the word line connection structures 108 are located at middle locations of the word lines WL.

In some examples, two word line connection structures connected with two adjacent word lines are staggered in the third direction. The third direction intersects the first direction and is perpendicular to the second direction.

As shown in FIG. 9B, two word line connection structures connected with two adjacent word lines are staggered in the third direction. Here, the term “staggered” may be understood to mean that the projections in the third direction of two word line connection structures connected with two adjacent word lines do not completely overlap. They can partially overlap or do not overlap at all. It is to be noted that, in examples of the present disclosure, for a plurality of word lines spaced from each other in the third direction, as shown in FIG. 9B, the two word line connection structures spaced by two word lines are aligned with each other in the third direction.

It can be understood that two adjacent word line connection structures being staggered may allow more space to accommodate the word line connection structures having cross sections (those formed by the X direction and the Y direction) with a larger size, so that the word lines and WLDs can be connected more reliably. At the same time, the word line connection structures spaced by other word line(s) being aligned may enable the whole region occupied by all the word line connection structures to be confined within a relatively small extent.

In some examples, two word line connection structures connected with two adjacent word lines are aligned in the third direction.

As shown in FIG. 9C, two word line connection structures connected with two adjacent word lines are aligned in the third direction. Here, the term “aligned” may be understood to mean that the projections in the third direction of two word line connection structures connected with two adjacent word lines completely overlap.

It can be understood that all the word line connection structures in a block are aligned, enabling the whole region occupied by all the word line connection structures to be confined within a small extent and in turn the area for disposing the bit lines to be maximized.

With reference to FIG. 6C and FIG. 7, in some examples, the first semiconductor structure 100 further includes a first contact connected with the word line WL and a second contact connected with the bit line BL, where the first contact and the second contact are disposed on the side proximate to the second semiconductor structure; the second semiconductor structure 200 further includes a third contact connected with the sensing amplifier and a fourth contact connected with the word line driver, where the third contact and the fourth contact are disposed on the side proximate to the first semiconductor structure, and the second contact and the third contact are connected at least through an interconnection layer between the first semiconductor structure and the second semiconductor structure, and so do the first contact and the fourth contact.

Here, the first contact can be understood as the word line connection structure 108 and the word line landing pad 104 in FIG. 6C, the second contact may be understood as the bit line contact 404 in FIG. 6C, the third contact may be understood as the part of the front-side metal interconnection layer that is connected to the sensing amplifier in FIG. 6C, and the fourth contact may be understood as the part of the front-side metal interconnection layer that is connected to the word line driver in FIG. 6C. The second contact and the third contact are connected at least through the second interconnection layer 400 between the first semiconductor structure and the second semiconductor structure, and so do the first contact and the fourth contact.

Here, the first contact can be understood as the word line connection structure 108 in FIG. 7, the second contact may be understood as the bit line connection structure 112 in FIG. 7, the third contact may be understood as the part of the front-side metal interconnection layer that is connected to the sensing amplifier in FIG. 7, and the fourth contact may be understood as the part of the front-side metal interconnection layer that is connected to the word line driver in FIG. 7. The second contact and the third contact are connected at least through the bonding interconnection structure 500 between the first semiconductor structure and the second semiconductor structure, and so do the first contact and the fourth contact. In some examples, at least one of the first contact or the second contact may be located at edges of the memory cell array, or located directly below the memory cell array.

In some examples, the first semiconductor structure 100 further includes a fifth contact connected with the capacitor with the fifth contact disposed on the side proximate to the second semiconductor structure; the second semiconductor structure 200 further includes a sixth contact connected with the common electrode with the sixth contact disposed on the side proximate to the first semiconductor structure. The fifth contact and the sixth contact are connected through the interconnection layer between the first semiconductor structure and the second semiconductor structure. The fifth contact may be located at the edge of the memory cell array.

With reference to FIGS. 6C and 7 and in connection with FIG. 5B, in some examples, the second semiconductor structure further includes a plurality of active regions isolated by an isolation region and the connection structures are disposed at the borders of the active regions and in the isolation region.

In some examples, the first insulation structures 206 spacing a plurality of active regions apart from each other are included in the first substrate 202 of the second semiconductor structure 200, and connection structures 204 may be disposed in the first insulation structures 206; and/or, the second insulation structures 208 spacing a plurality of well regions (P wells/N wells) apart from each other are further included in the first substrate 202 of the second semiconductor structure 200, and connection structures 204 may be disposed in the second insulation structures 208. The materials and locations of the first insulation structures 206 and the second insulation structures 208 have been mentioned above and will not be repeated here.

Here, disposing the connection structures 204 at the borders of the active regions and in the isolation region may prevent the connection structures extending through the first substrate from breaking the first control circuits or the structure of at least part of the peripheral circuit located in the first substrate.

With reference to FIGS. 6C and 7, in some examples, the memory device further includes a power supply wiring and the power supply wiring is disposed in the first interconnection layer.

In some examples, a portion of the metal interconnection lines (e.g., the Layer 4 metal layer 304 shown in FIGS. 6C and 7) in the first interconnection layer 300 serves as the power supply wiring connected with the wiring layer corresponding to at least part of the peripheral circuit through contacts (e.g. the Layer 4 contacts 303 shown in FIGS. 6C and 7). A portion of the metal interconnection lines of the first interconnection layer 300 (e.g. the Layer 3 metal layer 307 shown in FIGS. 6C and 7) serves as the wiring layer for peripheral circuit, and the wiring for the peripheral circuit is connected with at least part of the peripheral circuit through contacts (e.g. the connection structures 204 shown in FIGS. 6C and 7).

It is to be noted that in some other examples the locations of the power supply wiring and the wiring layer for the peripheral circuit may be exchangeable up and down. In some other examples, the power supply wiring and the wiring layer for the peripheral circuit may also be arranged at different locations in the same metal layer. In summary, examples of the present disclosure are not limited with respect to the position relationship between them.

It can be understood that the power supply on the back-side of the second semiconductor structure enables a shorter distance from the power source to the periphery circuit and the first control circuit, a smaller voltage drop over the wiring, and thus a higher utilization ratio of the power source. Meanwhile, the metal layers for interconnection of the peripheral circuit and the metal layers for arrangement of a power bus are disposed on the back side of the second semiconductor structure, so that the total number of the metal layers on the front side and the back side can be reduced, the process cost can be reduced and the sizes occupied by the metal layers can be reduced.

In some examples, the second semiconductor structure further includes at least one of a plurality of second control circuits or a datapath circuit with one second control circuit connected with one bank, where the at least one of the second control circuits or the datapath circuit are distributed in the gaps between the plurality of first control circuits.

Here, the second control circuit is a control circuit corresponding to the bank, such as the above-mentioned column decoding circuit, row decoding circuit, and the like. Each bank corresponds to a set of the column decoding circuit and the row decoding circuit. In addition to placing the peripheral circuit in the aforementioned spare regions, the column decoding circuits and the row decoding circuits can also be distributed in the corresponding locations below the banks.

Here, the datapath circuit is configured for multiple data transmissions and data conversions from outside the memory devices to the memory cell array; and the datapath circuit is configured to determine the order of the transmissions and ensure the quality of the data transmissions. The datapath circuit is closely related to the memory cell array in functionality and can be distributed in the corresponding locations below the banks.

In some examples, the border of the region where the second control circuit is disposed overlaps with borders of the gaps between adjacent banks.

Here, in consideration of the convenience of wiring, the set of column decoding circuit and row decoding circuit corresponding to each bank are disposed next to the corresponding locations below the respective banks. For example, the second control circuit may be disposed at the corresponding location below the gap between adjacent banks, so that the border of the region where the second control circuit is disposed overlaps with the borders of the gaps between the adjacent banks.

In this way, additional region needed by the second control circuits may be reduced to further increase the storage density of the memory device.

With reference to FIGS. 6C and 7, in some examples, the memory device further includes pads located on the side of the first interconnection layer away from the second semiconductor structure and electrically connected with the first interconnection layer.

Here, the pads 306 may be located on and electrically connected with the first interconnection layer. Illustratively, the pads 306 may be used as the fan-out pads of the memory device, so that the memory device can be electrically connected with an external device through the fan-out pads. The material of the pads 306 can be understood with reference to the material of the above-mentioned Layer 4 metal layer 304. For example, the material of the pads 306 includes aluminum, an aluminum alloy or other metal materials that are easy to be directly patterned through photolithography, or may also include copper, a copper alloy or other metal materials having good conductivity.

With reference to FIGS. 6C and 7, in some examples, the memory cell array includes a plurality of word lines WL extending in the first direction; a plurality of bit lines BL extending in the third direction; and the memory cell array includes a plurality of semiconductor pillars arranged in an array and memory structures each corresponding to each of the plurality of semiconductor pillars. The semiconductor pillar may be stacked with the corresponding memory structure such that the semiconductor pillar extends in the second direction and has a first end and a second end disposed opposite to each other in the second direction. The first end may be connected with the bit line and the second end connected with the memory structure. The word line may be coupled to at least one side of the semiconductor pillar. The second direction may be perpendicular to both the first direction and the third direction.

Here, the semiconductor pillar may be understood as the channel structure of the array transistor TA in FIG. 6C or 7. The memory structure may be understood as the capacitor C in FIG. 6C or 7.

In an example of the present disclosure, the semiconductor pillar extends in the second direction, e.g., the channel structure of the array transistor extends in the second direction. The array transistor is a vertical transistor, which facilitates reduction of its size. The array transistor and the memory structure are stacked in the second direction. The area-per-unit memory cell in the memory cell array may be the area of 4 units arrays (e.g., 4F²), which may improve the integrity of the memory device.

With reference to FIGS. 6C and 7, in some examples, the memory structure includes the capacitor C, which may include a cup-shaped capacitor, a cylinder-shaped capacitor or a pillar-shaped capacitor. Illustratively, each of the cup-shaped capacitor, the cylinder-shaped capacitor and the pillar-shaped capacitor includes a bottom electrode, a top electrode and a dielectric layer between the bottom electrode and the top electrode. It is to be noted that the bottom electrode of the capacitor is connected with the source of the array transistor, and the top electrode of the capacitor is connected with the common electrode for grounding. The capacitor is configured to store the written data.

It is to be noted that when the bottom electrodes of the cup-shaped capacitor, the cylinder-shaped capacitor and the pillar-shaped capacitor have the same area, the area of the top electrode of the cylinder-shaped capacitor is the largest, followed by the top electrodes of the cup-shaped capacitor and the pillar-shaped capacitor. Based on this, in some examples, the cylinder-shaped capacitor may be used as the memory cell of the memory device, which facilitates improving the integrity of the memory device.

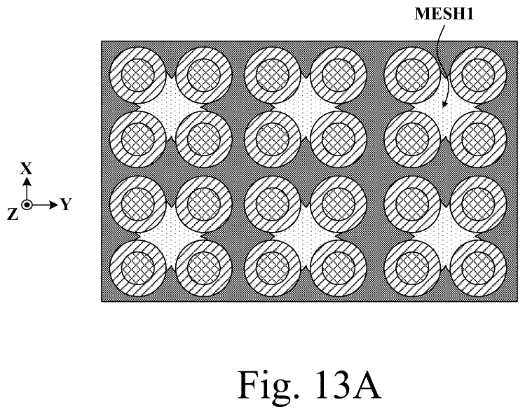

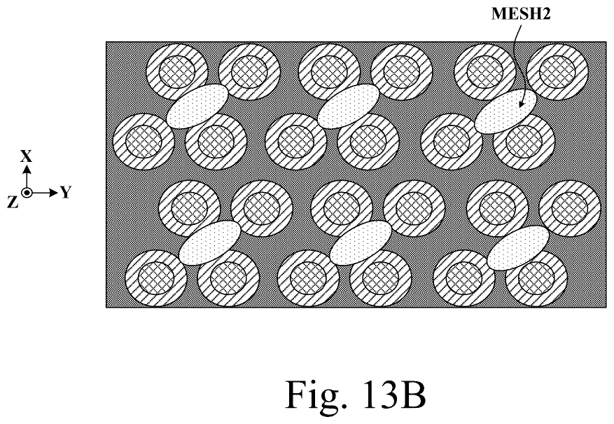

In some examples, a plurality of memory structures is arranged in a square shape or a hexagon shape. With reference to FIG. 13A, in an X-Y plane viewed from above, an array of the plurality of memory structures may be arranged in a square shape, and the gap between the four memory structures arranged in a square shape is a first gap MESH1. Referring to FIG. 13B, in an X-Y plane viewed from above, an array of the plurality of memory structures may be arranged in a hexagon shape, and the gap between the four memory structures arranged in a hexagon shape is a second gap MESH2. In practical applications, a plurality of memory structures may also be arranged in another pattern other than a square shape and a hexagon shape. Compared to the plurality of memory structures arranged in a square shape, the plurality of memory structures arranged in a hexagon shape may provide a higher density of arrangement. For example, the second gap MESH2 is smaller than the first gap MESH1, which facilitates improving the integrity of the memory device.

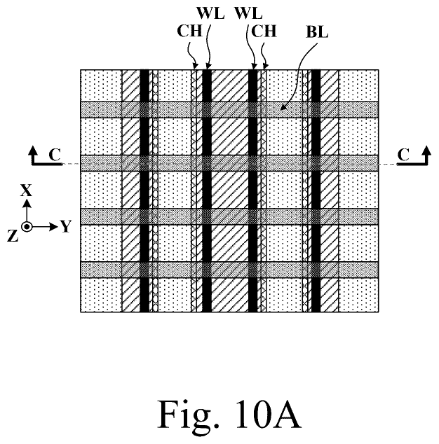

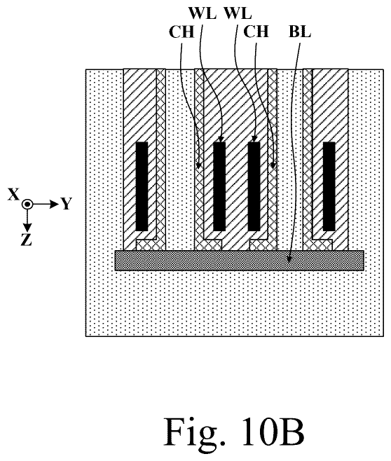

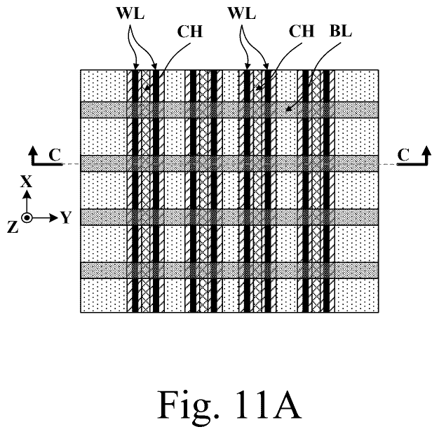

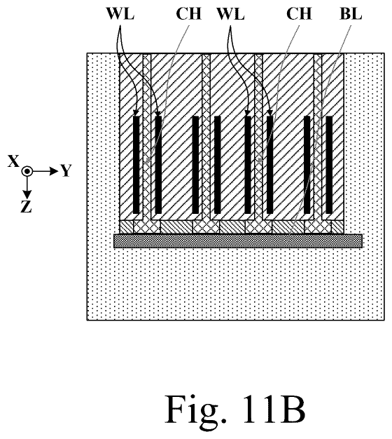

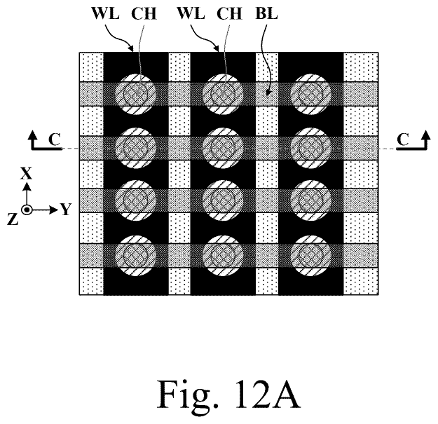

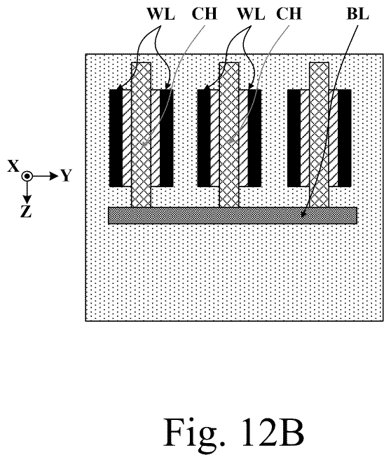

In some examples, with reference to FIGS. 10A and 10B, the word line WL may be coupled to one side of the semiconductor pillar CH to form a single-side gate structure; or with reference to FIGS. 11A and 11B, the word line WL may be coupled to two sides of the semiconductor pillar CH that are opposite to each other so that a double-side gate structure is formed; or with reference to FIGS. 12A and 12B, the word line WL may be coupled to all sides of the semiconductor pillar CH to form a gate-all-around structure.

In some examples, the material of the semiconductor pillar CH may include at least one of indium gallium zinc oxide, indium zinc oxide, gallium zinc oxide, indium gallium oxide, zinc oxide, indium oxide and gallium oxide. In some examples, the material of the semiconductor pillar CH may include indium gallium zinc oxide.

It can be understood that indium gallium zinc oxide has characteristics such as a high mobility, good homogeneity, low power consumption and low noises. A transistor having its channel formed with a semiconductor pillar CH including indium gallium zinc oxide has a relatively high field-effect mobility and a relatively high threshold voltage and can achieve better performance. Additionally, indium gallium zinc oxide can be fabricated directly through deposition or another process and is easy to process.

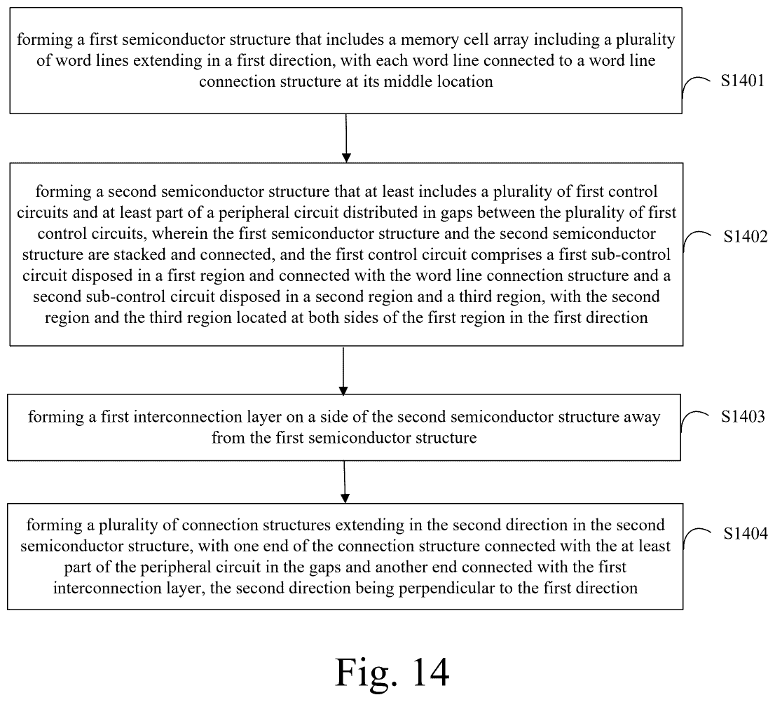

In a second aspect, examples of the present disclosure provide a method of fabricating a memory device. Referring to FIG. 14, which is a flow chart illustrating a method of fabricating a memory device provided in an example of the present disclosure, the method includes the following operations.

In operation S1401, a first semiconductor structure is formed to include a memory cell array including a plurality of word lines extending in a first direction, where each word line connected to a word line connection structure at its middle location.

In operation S1402, a second semiconductor structure is formed to at least include a plurality of first control circuits and at least part of a peripheral circuit distributed in the gaps between the first control circuits, where the first semiconductor structure and the second semiconductor structure are stacked and connected together. The first control circuit includes a first sub-control circuit disposed in a first region and connected with the word line connection structure; and the first control circuit may include a second sub-control circuit disposed in a second region and a third region, where the second region and the third region located at both sides of the first region in the first direction.

In operation S1403, a first interconnection layer is formed on a side of the second semiconductor structure away from the first semiconductor structure.

In operation S1404, a plurality of connection structures extending in the second direction are formed in the second semiconductor structure, where the connection structure has one end connected with the at least part of the peripheral circuit in the gaps and another end connected with the first interconnection layer. The second direction is perpendicular to the first direction.

It should be understood that the operations shown in FIG. 14 are not exclusive and another operation may be performed before, after or between any operation(s) in the shown operations and the order of the operations shown in FIG. 14 may be adjusted according to practical demands. As described above, the gates (word lines) and semiconductor pillars in a memory device may be disposed in a variety of relative position relationships, which may correspond to different methods of fabrication. In an example of the present disclosure, description will be given with the case, in which two gates corresponding to two adjacent semiconductor bodies are disposed back to back (the configuration shown in FIGS. 10A and 10B is a back-to-back configuration), taken as an example.

The first semiconductor structure, the second semiconductor structure, the first interconnection layer, and the connection structures may be formed in a variety of methods, several of which are illustrated in examples of the present disclosure. A process of forming the first semiconductor structure, the second semiconductor structure, the first interconnection layer, and the connection structures will be described in detail hereafter in connection with accompanying drawings.

During the process of performing operations S1401 to S1404, in some implementations, forming the first semiconductor structure, the second semiconductor structure and the first interconnection layer may include forming the second semiconductor structure on a first surface of a first substrate; forming the first semiconductor structure, the second semiconductor structure and the first interconnection layer may include forming a second interconnection layer on the second semiconductor structure; forming the first semiconductor structure, the second semiconductor structure and the first interconnection layer may include forming the first semiconductor structure on the second interconnection layer, connecting the first semiconductor structure and the second semiconductor structure through the second interconnection layer; forming the first semiconductor structure, the second semiconductor structure and the first interconnection layer may include forming the first interconnection layer on a second surface of the first substrate, where the first surface and the second surface are the two opposite surfaces of the first substrate in the thickness direction (e.g., the second direction).

In some examples, forming the first semiconductor structure may include forming a plurality of bit lines extending in the third direction; forming the first semiconductor structure may include forming a plurality of semiconductor pillars on surfaces of the bit lines, where the semiconductor pillars extend in the thickness direction of the first substrate; forming the first semiconductor structure may include forming a plurality of word lines extending in the first direction, where the word line is located on at least one side of the semiconductor pillar and both the first direction and the third direction are perpendicular to the thickness direction of the first substrate; and forming the first semiconductor structure may include forming a memory structure on the surface of each semiconductor pillar away from the bit lines.

In some examples, the composition materials of the word lines include a material with a resistivity smaller than a preset resistivity.

In some examples, the composition materials of the word lines include molybdenum. In some examples, the method may further include providing a third substrate; bonding the third substrate on the memory structures to form a bonded structure; the method may further include turning the bonded structure upside down to expose the second surface of the first substrate; and the method may further include forming the first interconnection layer on the second surface of the first substrate and then removing the third substrate.

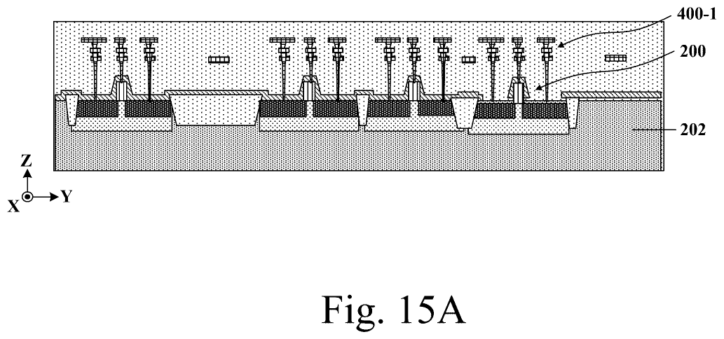

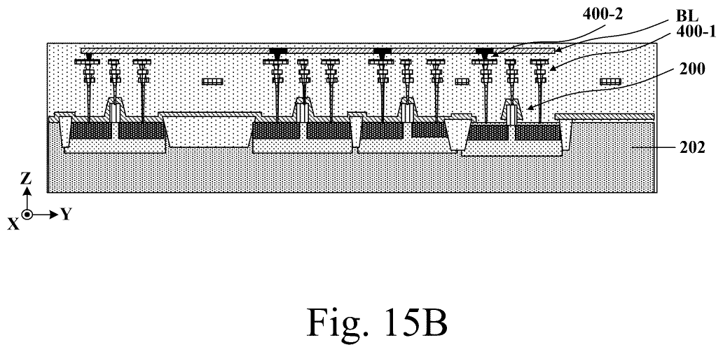

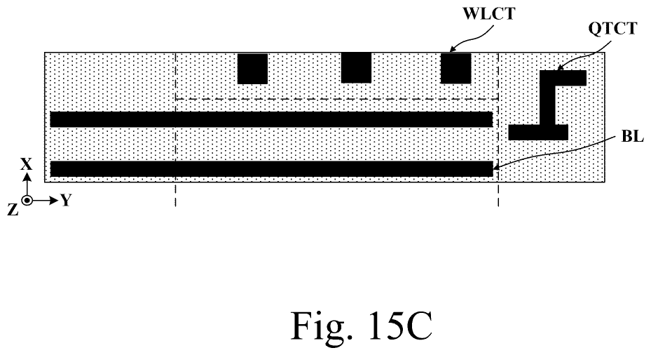

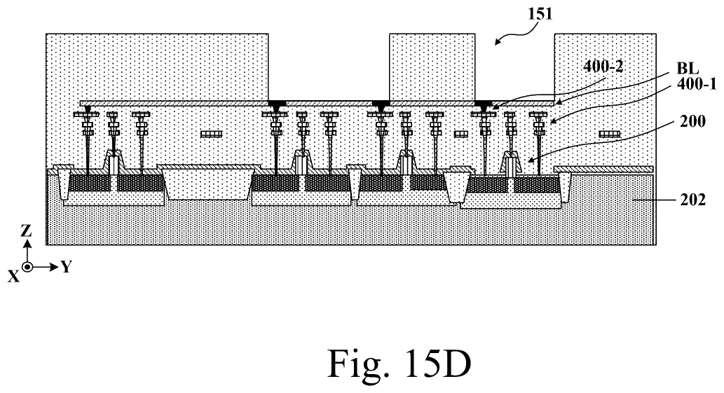

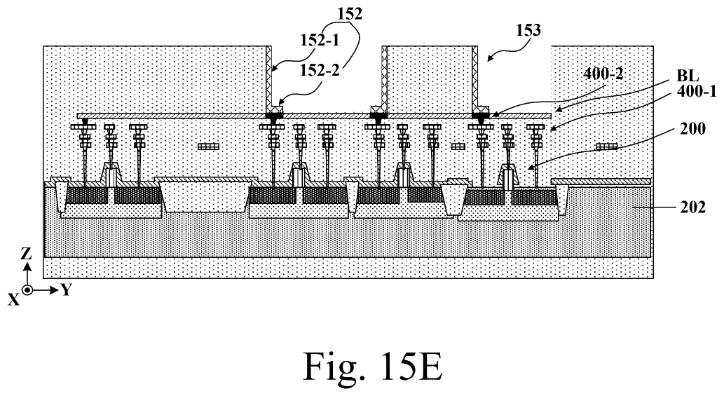

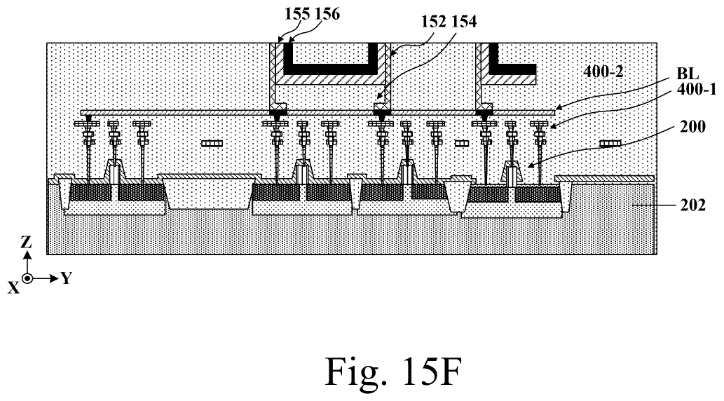

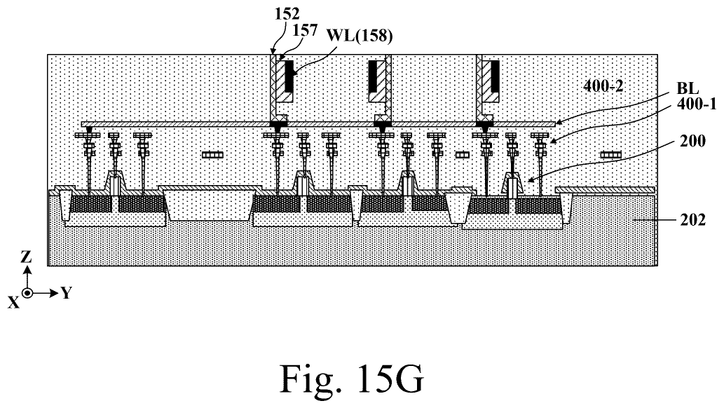

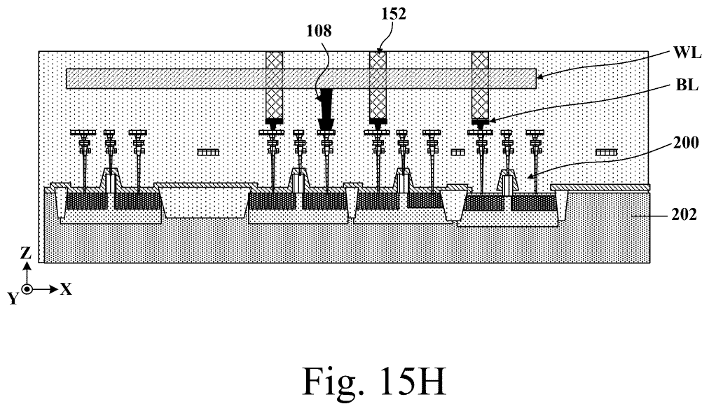

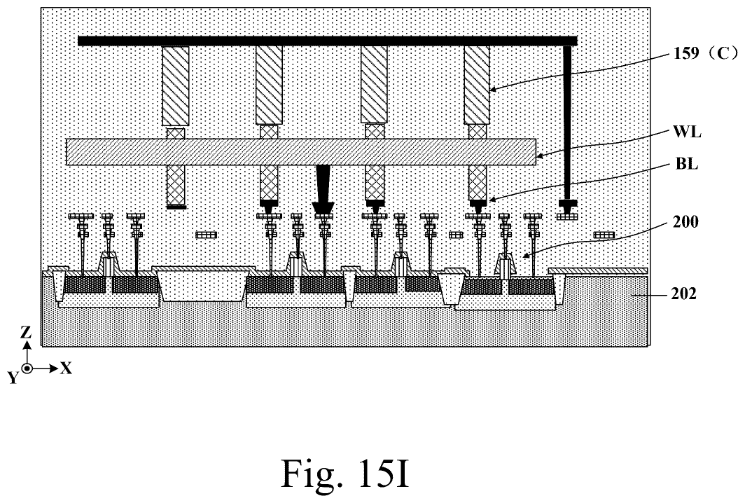

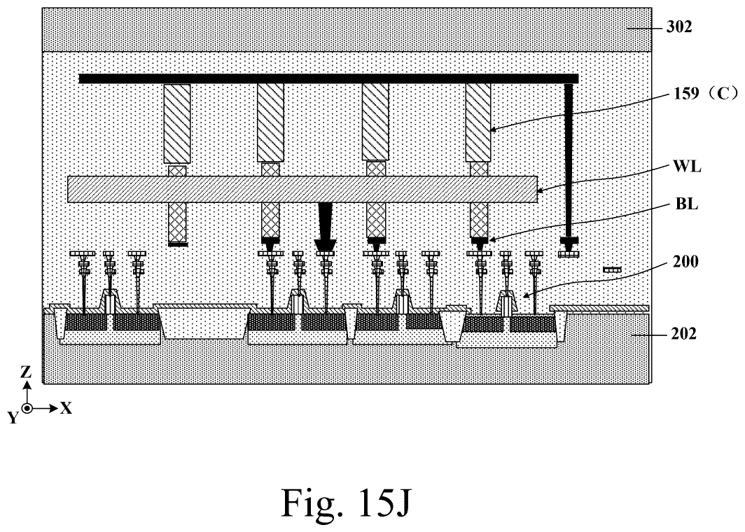

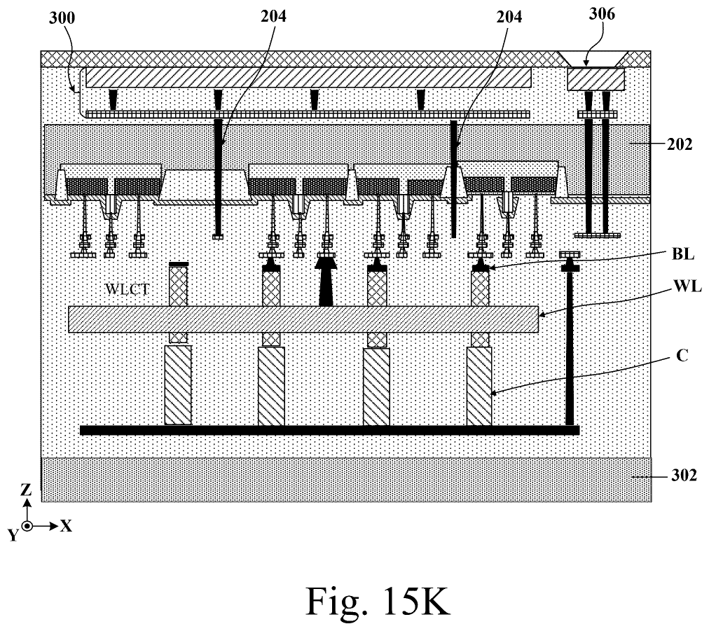

FIGS. 15A to 15K illustrate cross sections in a process of forming a memory device provided in an example of the present disclosure. It is to be noted that FIG. 15C is a top view corresponding to the phase of FIG. 15B. The process of forming the memory device will be described in detail hereafter in connection with accompanying drawings.

With reference to FIG. 15A, a first substrate 202 is provided, and a second semiconductor structure 200 is formed on a first surface of the first substrate 202. In some examples, the first substrate 202 may include a substrate composed of semiconductor materials such as silicon, germanium, silicon germanium or the like. In some other examples, the first substrate 202 may also be silicon on insulator or germanium on insulator. In some examples, the first substrate 202 has two surfaces disposed opposite to each other in the Z direction. The first surface may be the front side of the first substrate 202 and the second surface may be the opposite surface of the first substrate 202.

The second semiconductor structure 200 at least includes a plurality of first control circuits and at least part of a peripheral circuit distributed in the gaps between the plurality of first control circuits. In some examples, the second semiconductor structure 200 further includes a plurality of second control circuits. The peripheral circuit, the first control circuits and the second control circuits may be understood with reference to the foregoing description of these circuits. The specific composition and formatting position of the second semiconductor structure 200 will be described in detail hereafter.

In some examples, the at least part of the peripheral circuit includes a plurality of first portions and one second portion. At least one of the plurality of first portions or the second portion is connected with the first interconnection layer through the plurality of connection structures. The region where the one first portion and the first control circuit connected correspondingly with one respective block are disposed has a border overlapping with the border of the region where the respective block is disposed. The region where the second portion is disposed has a border overlapping with the borders of the gaps between adjacent blocks.

In some examples, the first region extends in the third direction, and the second region and the third region extend in the first direction. The third direction intersects the first direction and is perpendicular to the second direction. The first region is located at the middle section in the first direction of the region where the one first portion and the first control circuit connected correspondingly with the one respective block are disposed.

In some examples, the size in the third direction of the border of the first region is smaller than or equal to the size in the third direction of the border of the region where the block is disposed; the sum of the sizes in the first direction of the border of the first region and the border of the second and third regions is the same as the size in the first direction of the border of the region where the block is disposed.

In some examples, the first region includes a first sub-region and a second sub-region, which are staggered along the third direction; the second region and the third region are staggered or aligned along the first direction.

In some examples, the first sub-region and the second sub-region are of the same size and the second region and the third region are of the same size.

In some examples, the two second regions and third regions, in which the second sub-control circuits connected with two blocks adjacent in the third direction are disposed respectively, are located at the same or different corresponding locations in the respective blocks.

In some examples, the second semiconductor structure further includes at least one of a plurality of second control circuits or a datapath circuit, with one second control circuit connected with one bank. In some implementations, forming the second semiconductor structure further includes forming the at least part of the peripheral circuit and at least one of the plurality of second control circuits or the datapath circuit in the gaps between the plurality of first control circuits, where the second control circuit includes a row decoding circuit and a column decoding circuit. In some examples, forming the second control circuit includes forming at least one of the second control circuits or the datapath circuit at the locations overlapped with the gaps between adjacent banks in the second semiconductor structure.

In some examples, the process of forming the second semiconductor structure 200 may include forming a P-type well region (P well) and a N-type well region (N well) on the first substrate 202, with the P well being n-doped and the N well being p-doped respectively to form the desired semiconductor doped regions; and then, the process of forming the second semiconductor structure 200 may include forming gates on the surface of the substrate to obtain the peripheral circuit including peripheral transistor, the first control circuit and the second control circuit.

With continued reference to FIG. 15A, a portion 400-1 of the second interconnection layer is formed on the second semiconductor structure 200. In some examples, the portion 400-1 of the second interconnection layer may include one or more levels of metal layers and contacts in the respective metal layers (FIG. 15A shows the Layer 3 metal layers and the Layer 3 contacts) and is at least configured for connection of the transistors in the first control circuit and for fan-out of the sources, drains and gates of the transistors included in the first control circuit and the peripheral circuit. The portion 400-1 of the second interconnection layer includes a third contact connected with the sensing amplifier and a fourth contact connected with the word line driver.

With reference to FIG. 15B, it is continued with forming another portion 400-2 of the second interconnection layer and the bit lines BL in the first semiconductor structure on the second semiconductor structure 200. The bit lines BL extend in the third direction, e.g., the Y direction. The portion 400-1 and the other portion 400-2 of the second interconnection layer together form the second interconnection layer 400.

In some examples, the other portion 400-2 of the second interconnection layer may include a word line contact (e.g., the first contact), a bit line contact (e.g., the second contact) and a common electrode contact for capacitors. Only the bit line contact can be seen in FIG. 15B.

In some examples, the method of forming the second interconnection layer and the bit line includes, but is not limited to, forming trenches using an etching process first and then forming the metal layer and the various contacts using a deposition process.

With reference to FIG. 15C, the plurality of bit lines BLs all extend in the third direction, e.g., the Y direction, and are arranged at intervals in the first direction. The word line contacts WLCT are located at one side of the bit lines and have no interference with the bit lines, and other contacts QTCT may be located at other sides of the bit lines and have no interference with the bit line contacts and the word line contacts. It is to be noted that FIG. 15C is not the diagram viewed along the Z direction corresponding to FIG. 15B, but only a diagram viewed along the Z direction illustrating the fabrication phase corresponding to FIG. 15B. The position relationship between the bit line contacts, word line contacts and other contacts shown in FIG. 15C is only an example and not intended to limit examples of the present disclosure in the position relationship between the bit line contacts, word line contacts and other contacts.

With reference to FIG. 15D, a first dielectric layer is formed on the surface of the bit lines and first trenches 151 are formed in the first dielectric layer. The first trenches 151 are arranged in an array along the first direction and the third direction. In some examples, the material of the first dielectric layer includes, but is not limited to, silicon oxide; and the method of forming the dielectric layer includes, but is not limited to, a deposition process. The deposition process may be physical vapor deposition, chemical vapor deposition, or another deposition process. In some examples, the method of forming the trenches 151 includes, but is not limited to, a dry etching process.

With reference to FIG. 15E, a semiconductor material layer is formed over the sidewalls and the bottoms of the first trenches 151, at least portion of the semiconductor material layer at bottoms is removed to expose the surface of the bit lines, and the remaining of the semiconductor material layer forms a semiconductor pillar 152, including a semiconductor body 152-1 extending in the Z direction and optionally including a semiconductor accessory 152-2 extending in the Y direction. Based on the first trenches 151 with the semiconductor pillar 152 formed, second trenches 153 are formed to extend in the X direction.

In some examples, the material of the semiconductor material layer may include at least one of indium gallium zinc oxide, indium zinc oxide, gallium zinc oxide, indium gallium oxide, zinc oxide, indium oxide, and gallium oxide. The method of forming the semiconductor material layer includes, but is not limited to, a deposition process; and the method of removing at least portion of the semiconductor material layer at bottoms and forming the second trenches includes, but is not limited to, a dry etching process.

With reference to FIG. 15F, a dielectric material layer is formed in the second trench 153 and etched back to form a second dielectric layer 154 having a top surface lower than the top surface of the semiconductor pillar 152. A gate dielectric material layer 155, a gate material layer 156 and a dielectric material layer are formed sequentially on the top surface of the second dielectric layer 154 and the side walls of the second trench 153.

In some examples, the material of the dielectric material layer includes, but is not limited to, silicon oxide; the material of the gate dielectric material layer 155 includes, but is not limited to, a material with a high dielectric constant; and the material of the gate material layer 156 includes, but is not limited to, tungsten. The method of forming the dielectric material layer, the gate dielectric material layer 155, and the gate material layer 156 include, but is not limited to, a deposition process.

With reference to FIG. 15G, portions of the gate dielectric material layer 155 and the gate material layer 156 on the top surface of the second dielectric layer 154 are removed and the portions of the gate dielectric material layer 155 and the gate material layer 156 covering the side walls of the second trench are etched back to form a gate dielectric layer 157 and a gate 158, e.g., the word line WL. The plurality of word lines extend in the first direction and are arranged at intervals in the third direction. The top surface of the gate dielectric layer 157 and the gate 158 is lower than the top surface of the semiconductor pillar 152. In some examples, the method of removing the portions of the gate dielectric material layer 155 and the gate material layer 156 on the top surface of the second dielectric layer 154 and etching back the portions of the gate dielectric material layer 155 and the gate material layer 156 covering the side walls of the second trench includes, but is not limited to, dry etching.

It is to be noted that some other necessary processes are omitted here, for example, the process of doping the two ends of the semiconductor pillars 152 in the Z direction after formation of the semiconductor pillars 152 to form the sources and drains. Based on this, the semiconductor pillars 152 are configured to form the transistors TA.

FIG. 15H is a cross section along a Z-X cutting plane corresponding to FIG. 15G. The word line connection structure 108 can be seen in FIG. 15H. In some examples, the middle location is within the middle one-third section of the word line in the first direction. In some examples, two word line connection structures connected with two adjacent word lines are staggered in the third direction. The third direction intersects the first direction and is perpendicular to the second direction. In some examples, the word line connection structures extend in the second direction.

With reference to FIG. 15I, the memory structure 159 is formed on the surface of each semiconductor pillar 152 away from the bit lines. In some examples, the memory structure 159 may be a capacitor. In some examples, the capacitor includes a cup-shaped capacitor, a cylinder-shaped capacitor, or a pillar-shaped capacitor. In some examples, a plurality of capacitors is arranged in a square shape or a hexagon shape. The specific form of the capacitor here may be understood with reference to the forms of capacitor described above. The method of forming the capacitor is well known and will not be repeated here.

It is to be noted that the numbers of the semiconductor pillars 152 in FIGS. 15H and 15I are only for example and they are only used to illustrate a rough outline of various fabrication processes, numbers of the semiconductor pillars 152 may not be shown correspondingly.

With reference to FIG. 15J, a dielectric material layer is filled and a third substrate 302 is bonded on the dielectric material layer to form a bonded structure. It is to be noted that the third substrate 302 is a substrate used as a carrier. The only requirement is strong adhesion between the third substrate and the dielectric material layer and no electrical connection is required.

With reference to FIG. 15K, the bonded structure is turned upside down to expose the second surface of the substrate 202, e.g., the back side of the first substrate. The front side of the first substrate includes a plurality of active regions spaced apart by an isolation region. Connection structures 204 extending through the first substrate are formed in the Z direction at borders of the active regions (that can be understood as the edges of the active regions) and in the isolation region from the back surface of the first substrate. Subsequently, a first interconnection layer 300 is formed on the back side of the first substrate 202. The wiring layer for connection of at least part of the peripheral circuit and the power supply wiring are formed in the first interconnection layer 300. Pads 306 electrically connected with the first interconnection layer are formed on the side of the first interconnection layer away from the second semiconductor structure. In some examples, the connection structures 204 may be completed using the through-silicon via technique.

In some examples, the third substrate 302 may also be selectively removed in a subsequent process.

At this point, the fabrication of the memory device by using one method is completed, in which both the first semiconductor structure and the second semiconductor structure are grown on the same substrate, e.g., the first substrate 202. In this way, the number of the growth substrates to be used and the manufacturing cost can be reduced.

During the process of performing operations S1401 to S1404, in some examples, forming the first semiconductor structure, the second semiconductor structure and the first interconnection layer includes forming the second semiconductor structure on the first surface of the first substrate; forming the first semiconductor structure, the second semiconductor structure and the first interconnection layer includes forming a third interconnection layer and a first bonding layer that are stacked in this order on the second semiconductor structure; forming the first semiconductor structure on a second substrate; forming the first semiconductor structure, the second semiconductor structure and the first interconnection layer includes forming a fourth interconnection layer and a second bonding layer that are stacked in this order on the first semiconductor structure; forming the first semiconductor structure, the second semiconductor structure and the first interconnection layer includes bonding the first bonding layer and the second bonding layer together; forming the first semiconductor structure, the second semiconductor structure and the first interconnection layer includes connecting the first semiconductor structure and the second semiconductor structure through the third interconnection layer, the first bonding layer, the second bonding layer and the fourth interconnection layer; and forming the first semiconductor structure, the second semiconductor structure and the first interconnection layer includes forming the first interconnection layer on the second surface of the first substrate, where the first surface and the second surface are two surfaces disposed opposite to each other in the thickness direction of the first substrate.

In some examples, forming the first semiconductor structure includes forming a plurality of memory structures on the second substrate; forming the first semiconductor structure includes forming a semiconductor pillar on the surface of each memory structure away from the second substrate, where the semiconductor pillar extends in the thickness direction of the second substrate, e.g., in the second direction; forming a plurality of word lines extending in the first direction, where the word line is located on at least one side of the semiconductor pillar; forming the first semiconductor structure includes forming bit lines on the surface of the semiconductor pillars away from the memory structures, where the bit line extends in the third direction and both the first direction and the third direction are perpendicular to the thickness direction of the second substrate.

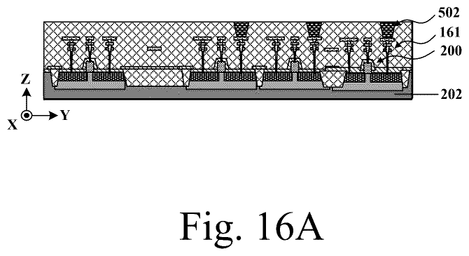

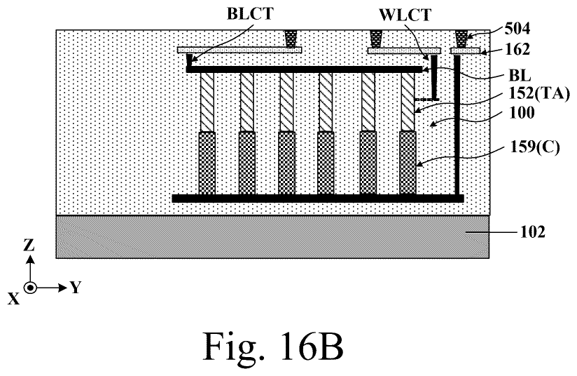

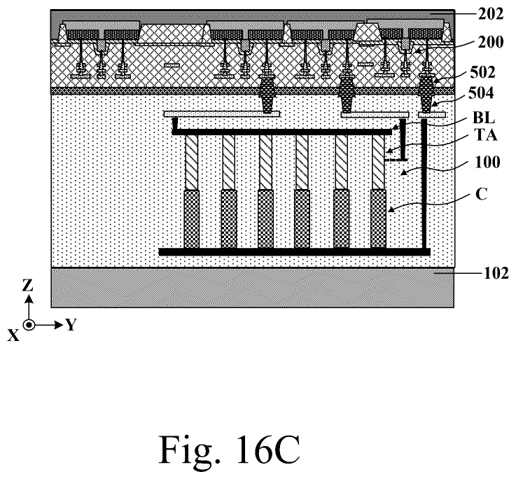

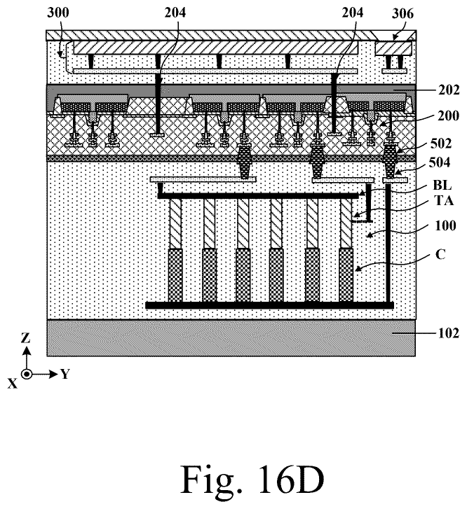

FIGS. 16A to 16D are second cross sections in a process of forming a memory device provided in an example of the present disclosure. The process of forming a memory device will be described in detail hereafter in connection with accompanying drawings.

With reference to FIG. 16A, a first substrate 202 is provided, and a second semiconductor structure 200 is formed on a first surface of the first substrate 202. The first substrate 202 may be understood with reference to the foregoing description in FIG. 15A and will not be repeated here. The components of the second semiconductor structure 200 and their forming locations and forming methods can be understood with reference to the foregoing description in FIG. 15A and will not be repeated here.

With continued reference to FIG. 16A, a third interconnection layer and a first bonding layer that are stacked are formed in this order on the second semiconductor structure 200. In some examples, the third interconnection layer 161 may include one or more levels of metal layers and contacts for the respective metal layers (FIG. 16A shows the Layer 3 metal layers and Layer 3 contacts). The first bonding layer may include first bonding contacts 502.

In some examples, the method of forming the third interconnection layer and the first bonding layer includes, but is not limited to, forming trenches using an etching process first and then forming the metal layers, the various contacts and the bonding contacts using a deposition process.

With continued reference to FIG. 16B, a second substrate 102 is provided and a first semiconductor structure 100 is formed on the second substrate 102. Forming the first semiconductor structure 100 may include forming a plurality of memory structures 159 on the second substrate 102. Forming the first semiconductor structure 100 may include forming a semiconductor pillar 152 on the surface of each memory structure away from the second substrate, where the semiconductor pillar extends in the thickness direction of the second substrate (e.g., the Z direction). Forming the first semiconductor structure 100 may include forming a plurality of word lines WL, each of which extends in the first direction (e.g., the X direction), on at least one side of the semiconductor pillars 152. Forming the first semiconductor structure 100 may include forming bit lines extending in the third direction (e.g., the Y direction) on the surface of the semiconductor pillars away from the memory structures.

In some examples, the memory structure 159 may be a capacitor. In some examples, the capacitor includes a cup-shaped capacitor, a cylinder-shaped capacitor, or a pillar-shaped capacitor. In some examples, a plurality of capacitors is arranged in a square shape or a hexagon shape. The specific form of the capacitor here may be understood with reference to the forms of capacitor described above. The method of forming the capacitor is relatively mature and will not be repeated here.

In some examples, the method of forming the semiconductor pillars 152 and the word lines WL can be understood with reference to the foregoing description in FIGS. 15D to 15F and will not be repeated here. It is to be noted that the bit lines here are formed on the surface of the semiconductor pillars 152 after formation of the semiconductor pillars 152.

It is to be noted that some other necessary processes are omitted here; for example, the process of doping the two ends of the semiconductor pillar 152 in the Z direction after formation of the semiconductor pillars 152 to form sources and drains may be omitted. Based on this, the semiconductor pillars 152 are configured to form transistors TA.

With continued reference to FIG. 16B, a fourth interconnection layer 164 and a second bonding layer that are stacked are formed in this order on the first semiconductor structure. In some examples, the fourth interconnection layer may include a single-layered or multi-layered interconnection layer (FIG. 16B shows the Layer 1 metal layer and Layer 1 contacts). The second bonding layer may include the second bonding contacts 504.

In some examples, the method of forming the fourth interconnection layer and the second bonding layer includes, but is not limited to, forming trenches using an etching process first and then forming the metal layers, the various contacts or the bonding contacts using a deposition process.

It is to be noted that the fabrication process illustrated in FIG. 16A and the fabrication process illustrated in FIG. 16B may be performed in series or in parallel. Examples of the present disclosure are not limited in their order.

With reference to FIG. 16C, the first bonding layer and the second bonding layer are bonded together with a bonding method including, but not limited to, mixed bonding. The first semiconductor structure and the second semiconductor structure are electrically connected with each other through the third interconnection layer, the first bonding layer, the second bonding layer and the fourth interconnection layer.

With reference to FIG. 16D, the front side of the first substrate 202 includes a plurality of active regions spaced apart by an isolation region. Connection structures 204 extending through the first substrate are formed in the Z direction at the borders of the active regions (e.g., that can be understood as the edges of the active regions) and in the isolation region from the back surface of the first substrate 202. Subsequently, a first interconnection layer 300 is formed on the back side of the first substrate 202. The wiring layer for connection of at least part of the peripheral circuit and the power supply wiring are formed in the first interconnection layer 300. Pads 306 electrically connected with the first interconnection layer are formed on the side of the first interconnection layer away from the second semiconductor structure. In some examples, the memory structures 159 may be completed using the through-silicon via technique.

At this point, the fabrication of the memory device by using another method is completed. In this another method, the first semiconductor structure and the second semiconductor structure are fabricated through growth on different substrates respectively. In this way, the problem of mutual constraints between the fabrication procedures of the memory cell array and the peripheral circuit can be solved to shorten the development period of the memory device.

Examples of the present disclosure further provide a system including the memory device in any of the above-described examples of the present disclosure.

In some examples, the memory device includes a dynamic random access memory.

In some examples, the system further includes a memory controller connected with and configured to control the memory device. It can be understood that “one example” or “an example” mentioned throughout the specification means that particular features, structures or characteristics in association with that example may be included in at least one example of present disclosure. Therefore, “in one example” or “in an example” mentioned throughout the specification refers not necessarily to the same example. Moreover, those particular features, structures or characteristics may be combined in one or more examples in any suitable method. It can be understood that, in various examples of the present disclosure, the ordinal numbers of the various processes above are not intended to indicate that the processes must be performed in any sequential order, and the various processes should be performed in an order determined depending on their functions and inherent logic. Implementation of examples of the present disclosure is not limited in this respect. The ordinal numbers in the above-mentioned examples of the present disclosure are only for the purpose of description and do not represent the advantages or disadvantages of the examples.

The above is only some examples of the present disclosure and does not limit the patent scope of the present disclosure. Any equivalent structural transformation made under the inventive concept of the present disclosure using the content of the present disclosure specification and drawings, or those directly/indirectly applied in other related technical fields, should fall in the patent protection scope of the present disclosure.

What is claimed is:

1. A memory device, comprising:
a first semiconductor structure comprising a memory cell array, wherein the memory cell array comprises a plurality of word lines extending in a first direction with each of the word lines connected to a word line connection structure at its middle location;
a second semiconductor structure at least comprising a plurality of first control circuits and at least part of a peripheral circuit distributed in gaps between the plurality of first control circuits, wherein the first semiconductor structure and the second semiconductor structure are stacked and connected, and the first control circuit comprises a first sub-control circuit disposed in a first region and connected with the word line connection structure and a second sub-control circuit disposed in a second region and a third region, wherein the second region and the third region are located at both sides of the first region in the first direction;
a first interconnection layer located on a side of the second semiconductor structure away from the first semiconductor structure; and
a plurality of connection structures, wherein each of the plurality of connection structures extends in a second direction in the second semiconductor structure and has one end connected with the at least part of the peripheral circuit in the gaps and another end connected with the first interconnection layer, and wherein the second direction is perpendicular to the first direction.

2. The memory device of claim 1, wherein:
the memory device further comprises a second interconnection layer between the first semiconductor structure and the second semiconductor structure, and
the first semiconductor structure and the second semiconductor structure are connected through the second interconnection layer.

3. The memory device of claim 1, wherein:
the memory device further comprises a third interconnection layer, a first bonding layer, a second bonding layer, and a fourth interconnection layer stacked between the first semiconductor structure and the second semiconductor structure, and
the first semiconductor structure and the second semiconductor structure are connected through the third interconnection layer, the first bonding layer, the second bonding layer, and the fourth interconnection layer.

4. The memory device of claim 1, wherein the middle location is within a middle one-third section of the word line in the first direction.

5. The memory device of claim 1, wherein:
two word line connection structures connected with two adjacent word lines are staggered in a third direction, and
the third direction intersects the first direction and is perpendicular to the second direction.

6. The memory device of claim 1, wherein:
the memory cell array comprises a plurality of banks each comprising a plurality of blocks, and
one of the first control circuits is connected with one of the plurality of blocks and the peripheral circuit is connected with each of the plurality of banks.

7. The memory device of claim 6, wherein:
the second semiconductor structure further comprises at least one of a plurality of second control circuits or a datapath circuit,
one of the second control circuits is connected with one of the banks, and
the at least one of the second control circuits or the datapath circuit are distributed in the gaps between the plurality of first control circuits.

8. The memory device of claim 6, wherein:
the at least part of the peripheral circuit comprises a plurality of first portions and one second portion,
at least one of the plurality of first portions or the second portion is connected with the first interconnection layer through the plurality of connection structures,
a region where one of the first portions and the first control circuit are connected correspondingly with one respective block are disposed has a border overlapping with a border of a region where the respective block is disposed, and
a region where the second portion is disposed has a border overlapping with borders of the gaps between adjacent blocks.

9. The memory device of claim 8, wherein:
the first region extends in a third direction,
the second region and the third region extend in the first direction,
the third direction intersects the first direction and is perpendicular to the second direction, and
the first region is located at the middle section in the first direction of the region where one of the first portions and the first control circuit is correspondingly connected with one respective block are disposed.

10. The memory device of claim 1, wherein:
the first sub-control circuit comprises a word line driver,
the second sub-control circuit comprises a sensing amplifier, and
the sensing amplifier is connected with bit lines in a block.

11. The memory device of claim 1, wherein the peripheral circuit comprises at least one of a local control circuit for data lines, a data bus switching circuit, a data input/output circuit, a data input/output control circuit, a one-time programmable memory, a data error correction circuit, a row hammer defense circuit, a command buffer, a command decoder, an address buffer, a data buffer, or a mode register.

12. The memory device of claim 1, wherein:
the second semiconductor structure comprises a plurality of active regions spaced apart by an isolation region, and
the connection structures are disposed at borders of the active regions and in the isolation region.

13. The memory device of claim 1, wherein the memory cell array comprises:
a plurality of bit lines extending in a third direction; and
a plurality of semiconductor pillars arranged in an array and a plurality of memory structures each corresponding to one of the plurality of semiconductor pillars,
wherein a semiconductor pillar and its corresponding memory structure are disposed in a stacking configuration,
wherein the semiconductor pillar extends in a second direction and has a first end and a second end disposed opposite to each other in the third direction,
wherein the first end is connected with the bit line and the second end is connected with the memory structure,
wherein the word line is coupled to at least one side of the semiconductor pillar, and
wherein the third direction intersects the first direction and is perpendicular to the second direction.

14. A method of fabricating a memory device, comprising:
forming a first semiconductor structure that comprises a memory cell array comprising a plurality of word lines extending in a first direction, wherein each of the word lines is connected to a word line connection structure at its middle location;
forming a second semiconductor structure that comprises a plurality of first control circuits and at least part of a peripheral circuit distributed in gaps between the first control circuits, wherein the first semiconductor structure and the second semiconductor structure are stacked and connected, the first control circuit comprises a first sub-control circuit disposed in a first region and connected with the word line connection structure and a second sub-control circuit disposed in a second region and a third region, wherein the second region and the third region are located at both sides of the first region in the first direction;
forming a first interconnection layer on a side of the second semiconductor structure away from the first semiconductor structure; and
forming a plurality of connection structures extending in a second direction in the second semiconductor structure, wherein one end of the connection structure is connected with the at least part of the peripheral circuit in the gaps and another end of the connection structure connected with the first interconnection layer, and wherein the second direction is perpendicular to the first direction.

15. The method of claim 14, wherein the forming the first semiconductor structure, the second semiconductor structure, and the first interconnection layer comprises:
forming the second semiconductor structure on a first surface of a first substrate;
forming a second interconnection layer on the second semiconductor structure;
forming the first semiconductor structure on the second interconnection layer, wherein the first semiconductor structure and the second semiconductor structure are connected through the second interconnection layer; and
forming the first interconnection layer on a second surface of the first substrate, wherein the first surface and the second surface are two surfaces disposed opposite to each other in the second direction.

16. The method of claim 15, wherein forming the first semiconductor structure comprises:
forming a plurality of bit lines extending in a third direction;
forming a plurality of semiconductor pillars on the surface of the bit lines, wherein the semiconductor pillars extend in the second direction;
forming a plurality of word lines extending in the first direction, wherein the word line is located on at least one side of the semiconductor pillar, and the third direction intersects the first direction and is perpendicular to the second direction; and
forming a memory structure on a surface of each of the semiconductor pillars away from the bit lines.

17. The method of claim 16, further comprising:
providing a third substrate;
bonding the third substrate on the memory structures to form a bonded structure;
turning the bonded structure upside down to expose the second surface of the first substrate; and
forming the first interconnection layer on the second surface of the first substrate and then removing the third substrate.

18. The method of claim 14, wherein forming the first semiconductor structure, the second semiconductor structure, and the first interconnection layer comprises:
forming the second semiconductor structure on a first surface of a first substrate;
forming a third interconnection layer and a first bonding layer that are stacked in this order on the second semiconductor structure;
forming the first semiconductor structure on a second substrate;
forming a fourth interconnection layer and a second bonding layer that are stacked in this order on the first semiconductor structure;
bonding the first bonding layer and the second bonding layer together, wherein the first semiconductor structure and the second semiconductor structure are connected through the third interconnection layer, the first bonding layer, the second bonding layer, and the fourth interconnection layer; and
forming the first interconnection layer on a second surface of the first substrate, wherein the first surface and the second surface are two surfaces disposed opposite to each other in the second direction.

19. The method of claim 18, wherein forming the first semiconductor structure comprises:
forming a plurality of memory structures on the second substrate;
forming a semiconductor pillar on the surface of each of the memory structures away from the second substrate, wherein the semiconductor pillar extends in the second direction;
forming a plurality of word lines extending in the first direction, wherein the word line is located on at least one side of the semiconductor pillar; and
forming a bit line on the surface of the semiconductor pillar away from the memory structure, wherein the bit line extends in a third direction, and the third direction intersects the first direction and is perpendicular to the second direction.

20. A memory system, comprising:
a memory device, comprising:
a first semiconductor structure comprising a memory cell array, wherein the memory cell array comprises a plurality of word lines extending in a first direction with each of the word lines connected to a word line connection structure at its middle location;
a second semiconductor structure comprising a plurality of first control circuits and at least part of a peripheral circuit distributed in gaps between the plurality of first control circuits, wherein the first semiconductor structure and the second semiconductor structure are stacked and connected, and the first control circuit comprises a first sub-control circuit disposed in a first region and connected with the word line connection structure and a second sub-control circuit disposed in a second region and a third region, wherein the second region and the third region are located at both sides of the first region in the first direction;
a first interconnection layer located on a side of the second semiconductor structure away from the first semiconductor structure; and
a plurality of connection structures, wherein each of the plurality of connection structures extends in a second direction in the second semiconductor structure and has one end connected with the at least part of the peripheral circuit in the gaps and another end connected with the first interconnection layer, and wherein the second direction is perpendicular to the first direction.
